(19) United States
(12) Patent Application Publication
(10) Pub. No.: US 2026/0060134 A1
(43) Pub. Date: Feb. 26, 2026

(54) SEMICONDUCTOR PACKAGE

(71) Applicant: Samsung Electronics Co., Ltd., Suwon-si (KR)

(72) Inventors: Junghoon Kang, Suwon-si (KR); Jihye Shim, Suwon-si (KR)

(21) Appl. No.: 19/269,732

(22) Filed: Jul. 15, 2025

(30) Foreign Application Priority Data
Aug. 22, 2024 (KR) 10-2024-0112662

(51) Int. Cl. H01L 23/31; H01L 21/78; H01L 23/00; H01L 23/48; H01L 25/18; H10B 80/00; H10D 80/30

(52) U.S. Cl. CPC H01L 23/3135; H01L 24/29; H01L 25/18; H10B 80/00; H10D 80/30; H01L 21/78; H01L 23/481; H01L 24/16; H01L 24/32; H01L 24/73; H01L 24/81; H01L 24/83; H01L 24/92; H01L 2224/16148; H01L 2224/29007; H01L 2224/29036; H01L 2224/32145; H01L 2224/73104; H01L 2224/81191; H01L 2224/81203; H01L 2224/83191; H01L 2224/83203; H01L 2224/9211; H01L 2225/06513; H01L 2225/06524; H01L 2225/06541

(57) ABSTRACT

A semiconductor package may include a first semiconductor chip, second semiconductor chips stacked on the first semiconductor chip in a vertical direction, adhesive layers interposed between the first semiconductor chip and one of the second semiconductor chips and between the second semiconductor chips, and a molding member on the first semiconductor chip. Edges of the adhesive layers may be positioned inward from sidewalls of the second semiconductor chips. The molding member may cover at least sidewalls of the second semiconductor chips and sidewalls of the adhesive layers. The molding member may fill edge gaps defined by the sidewalls of the adhesive layers and edges of upper surfaces and lower surfaces of the second semiconductor chips.

### CROSS-REFERENCE TO RELATED APPLICATION

This application claims priority under 35 USC § 119 to Korean Patent Application No. 10-2024-0112662, filed on Aug. 22, 2024, in the Korean Intellectual Property Office KIPO, the contents of which are incorporated by reference herein in their entirety.

### BACKGROUND

Various example embodiments relate to a semiconductor package. Particularly, various example embodiments relate to a multi-chip package including a plurality of stacked chips.

A High Bandwidth Memory (HBM) package includes a plurality of memory chips that are vertically stacked on a logic chip. The plurality of memory chips may be bonded to each other by an adhesive layer. In order for the HBM package to have excellent performance and durability, the bonding between the memory chips should be reliable.

### SUMMARY

Various example embodiments provide a semiconductor package having excellent electrical characteristics.

According to some example embodiments, there is provided a semiconductor package. The semiconductor package may include semiconductor chips including a first semiconductor chip and second semiconductor chips stacked on the first semiconductor chip in a vertical direction, adhesive layers interposed between vertically adjacent semiconductor chips, and a molding member on the first semiconductor chip. Edges of the adhesive layers may be positioned inward from sidewalls of the second semiconductor chips. The molding member may cover the sidewalls of the second semiconductor chips and sidewalls of the adhesive layers. The molding member may fill edge gaps between the vertically adjacent semiconductor chips and extending to sidewalls of a respective adhesive layer between the vertically adjacent semiconductor chips.

According to some example embodiments, there is provided a semiconductor package. The semiconductor package may include semiconductor chips including a first semiconductor chip, second semiconductor chips stacked on the first semiconductor chip in a vertical direction, and a third semiconductor chip stacked on the second semiconductor chips in a vertical direction, adhesive layers interposed between vertically adjacent semiconductor chips, and a molding member covering sidewalls of the second semiconductor chips and sidewalls of the adhesive layers. Edges of the adhesive layers may be positioned inward from the sidewalls of the second semiconductor chips. The molding member may contact the sidewalls of the adhesive layers and edge portions of the upper surfaces and lower surfaces of the second semiconductor chips. Each of the second semiconductor chips includes a substrate, through-electrode structures passing through the substrate, first conductive pads on a lower surface of the substrate, second conductive pads on an upper surface of the substrate, and a protective pad on an edge portion of the lower surface of the substrate. The first conductive pads may be electrically connected to the through-electrode structures, respectively. The second conductive pads may be electrically connected to the through-electrode structures, respectively. The protective pad may be formed of a material that is the same as a material of the second conductive pads.

According to some example embodiments, there is provided a semiconductor package. The semiconductor package may include a first semiconductor chip including logic circuitry, a second semiconductor chip, a third semiconductor chip, and a fourth semiconductor chip sequentially stacked in a vertical direction on the first semiconductor chip, non-conductive films including a first non-conductive film interposed between the first semiconductor chip and the second semiconductor chip, a second non-conductive film interposed between the second semiconductor chip and the third semiconductor chip, and a third non-conductive film interposed between the third semiconductor chip and the fourth semiconductor chip in the vertical direction to bond the first semiconductor chip, the second semiconductor chip, the third semiconductor chip, and the fourth semiconductor chip together, an epoxy molding compound covering sidewalls of the second semiconductor chip, the third semiconductor chip, and the fourth semiconductor chip and sidewalls of the non-conductive films, and a protective pad including a metal material disposed at an edge portion of a lower surface of at least one of the second semiconductor chip, the third semiconductor chip, and the fourth semiconductor chip. The semiconductor chip, the third semiconductor chip, and the fourth semiconductor chip may include memory circuits. Edges of the non-conductive films may be positioned inward from sidewalls of the second semiconductor chip, the third semiconductor chip, and the fourth semiconductor chip. The epoxy molding compound may fill edge gaps between the first semiconductor chip and the second semiconductor chip, the second semiconductor chip and the third semiconductor chip, and the third semiconductor chip and the fourth semiconductor chip and the edge gaps may extend to the sidewalls of the non-conductive films.

According to example embodiments, the semiconductor package may include the semiconductor chips that are vertically stacked and bonded to each other by the adhesive layer. The adhesive layer may not be formed at the edges of the upper surface and the lower surface of the semiconductor chips. The molding member may be at the edges of the upper surface and the lower surface of the semiconductor chips. An adhesive layer fillet that would protrude outward from a sidewall of each of the semiconductor chips may be prevented from forming, and thus, reliability of the semiconductor package may be improved and failures caused by the adhesive layer fillet may be prevented.

However, the effects of the present invention are not limited to the effects mentioned above, and may be variously expanded within the scope of the spirit and scope of the inventive concept as laid out in the claims.

### BRIEF DESCRIPTION OF THE DRAWINGS

Various example embodiments will be more clearly understood from the following detailed description taken in conjunction with the accompanying drawings. FIGS. 1 to 27 represent various non-limiting, example embodiments as described herein.

FIG. 1 is a cross-sectional view illustrating a semiconductor package according to example embodiments;

FIGS. 2 to 4 are plan views illustrating positions of protective pads and adhesive layers included in semiconductor chips in the semiconductor package according to example embodiments;

FIG. 5 is a cross-sectional view illustrating a semiconductor package according to some example embodiments;

FIGS. 6 to 25 are cross-sectional views and plan views illustrating a method of manufacturing a semiconductor package according to example embodiments;

FIG. 26 is a cross-sectional view illustrating a semiconductor package according to example embodiments;

FIG. 27 is a cross-sectional view illustrating an electronic device according to example embodiments.

### DETAILED DESCRIPTION

Hereinafter, various example embodiments will be described in detail with reference to the accompanying drawings. The invention may, however, be embodied in many different forms and should not be construed as limited to the example embodiments set forth herein. It should also be emphasized that the disclosure provides details of alternative examples, but such listing of alternatives is not exhaustive. Furthermore, any consistency of detail between various examples should not be interpreted as requiring such detail.

Items described in the singular herein may be provided in plural, as can be seen, for example, in the drawings. Thus, the description of a single item that is provided in plural in the drawings should be understood to be applicable to the remaining plurality of items unless context indicates otherwise.

In the following description, when a material, a layer (film), a region, a pad, an electrode, a pattern, a structure or a process are referred to using an ordinal number such as “first”, “second” and/or “third”, the reference is not intended to describe these elements, but merely act as a label to distinguish the material, the layer (film), the region, the electrode, the pad, the pattern, the structure or the process from one another. Therefore, “first”, “second” and/or “third” may be used selectively or interchangeably for the material, the layer (film), the region, the electrode, the pad, the pattern, the structure or the process and the same material, layer (film), region, pad, electrode, pattern, structure or process may have a different ordinal number in a different portion of the description or claims.

Hereinafter, a direction parallel to an upper surface of a substrate or a wafer is referred to as a horizontal direction, and a direction perpendicular to the upper surface of a substrate or a wafer is referred to as a vertical direction.

Throughout the specification, when a component is described as “including” a particular element or group of elements, it is to be understood that the component is formed of only the element or the group of elements, or the element or group of elements may be combined with additional elements to form the component, unless the context indicates otherwise. The term “consisting of,” on the other hand, indicates that a component is formed only of the element(s) listed.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

As used herein, components described as being “electrically connected” are configured such that an electrical signal can be conducted from one component to the other (although such electrical signal may be attenuated in strength as it is conducted and may be selectively transferred).

Terms such as “same,” “equal,” etc. as used herein when referring to features such as orientation, layout, location, shapes, sizes, compositions, amounts, or other measures do not necessarily mean an exactly identical feature but is intended to encompass nearly identical features including typical variations that may occur resulting from conventional manufacturing processes. The term “substantially”may be used herein to emphasize this meaning.

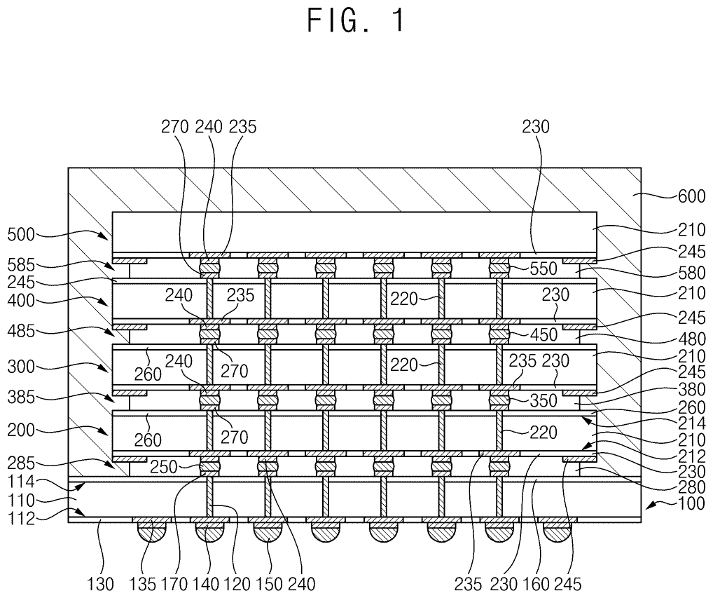

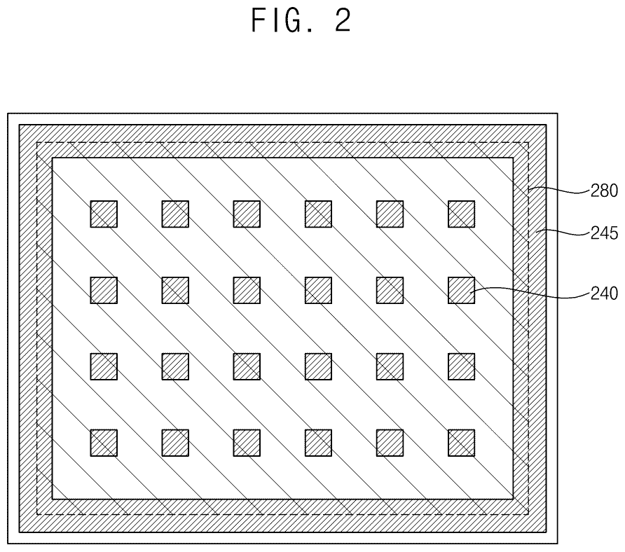

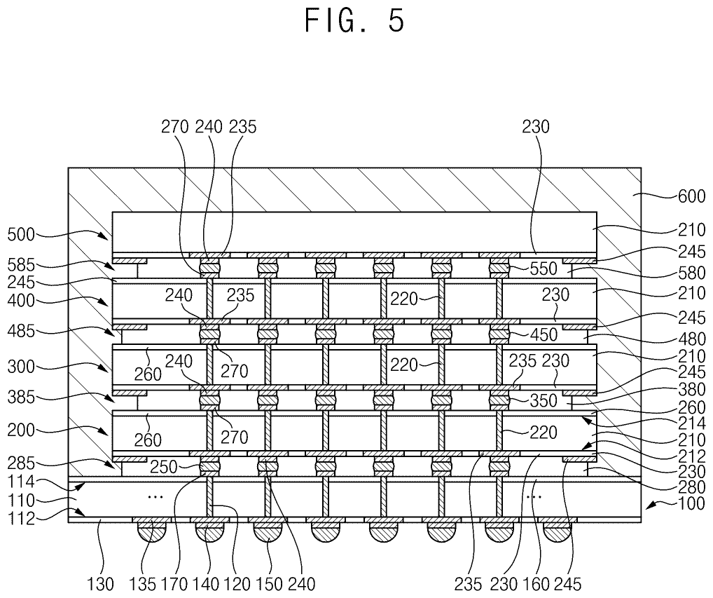

FIG. 1 is a cross-sectional view illustrating a semiconductor package according to example embodiments. FIGS. 2 to 4 are plan views illustrating positions of protective pads and adhesive layers included in semiconductor chips in the semiconductor package according to example embodiments. FIG. 5 is a cross-sectional view illustrating a semiconductor package according to some example embodiments.

FIGS. 2 to 4 illustrate layouts of the protective pads and positions of the adhesive layers included in a second semiconductor chip. However, the protective pads included in other semiconductor chips (e.g., third through fifth semiconductor chips) may also have a layout the same as the layouts of the protective pads shown in FIGS. 2 to 4.

Referring to FIG. 1, the semiconductor package may include a first semiconductor chip 100, second to fifth semiconductor chips 200, 300, 400 and 500 sequentially stacked on the first semiconductor chip 100, adhesive layers 280, 380, 480 and 580 interposed between the first to fifth semiconductor chips 100, 200, 300, 400 and 500, and a molding member 600 formed on the first semiconductor chip 100 and covering sidewalls of the second to fifth semiconductor chips 200, 300, 400 and 500 and sidewalls of the adhesive layers 280, 380, 480 and 580.

Although the semiconductor package including the four semiconductor chips 200, 300, 400 and 500 stacked on the first semiconductor chip 100 is illustrated, the number of semiconductor chips stacked on the first semiconductor chip 100 is not limited thereto and other embodiments may have other numbers of semiconductor chips. In example embodiments, the semiconductor package may be a high bandwidth memory (HBM) package.

In example embodiments, the first semiconductor chip 100 may include a buffer die. The first semiconductor chip 100 may include, for example, a logic device such as a controller. Each of the second to fifth semiconductor chips 200, 300, 400 and 500 may include a core die. Each of the second to fifth semiconductor chips 200, 300, 400 and 500 may include, for example, a volatile memory device such as a DRAM device or an SRAM device, or, for example, a nonvolatile memory device such as a flash memory device or an EEPROM device. Each of the second to fourth semiconductor chips 200, 300 and 400 may be referred to as a middle core die, and the fifth semiconductor chip 500 may be referred to as a top core die.

The first semiconductor chip 100 may be referred to as a logic chip or a logic die, and each of the second to fifth semiconductor chips 200, 300, 400 and 500 may be referred to as a memory chip or a memory die. The first semiconductor chip 100 may include logic circuitry for performing as a logic device. Each of the second to fifth semiconductor chips 200, 300, 400 and 500 may include memory circuitry for performing as memory devices.

In example embodiments, an upper surface of the first semiconductor chip 100 may have a first size. Upper surfaces of the second to fifth semiconductor chips 200, 300, 400, and 500 may have the same size, and may have a second size less than the first size. Sidewalls of the second to fifth semiconductor chips 200, 300, 400, and 500 stacked on the first semiconductor chip 100 may be aligned in the vertical direction.

The first semiconductor chip 100 may include a first substrate 110 having a first surface 112 and a second surface 114 being opposite to each other in the vertical direction, a first through-electrode structure 120 passing through the first substrate 110, a first insulating interlayer 130 disposed under the first surface 112 of the first substrate 110, a first conductive pad 140 disposed under the first insulating interlayer 130, a first external connecting member 150 disposed under the first conductive pad 140, a first insulating pattern structure 160 on the second surface 114 of the first substrate 110, and a second conductive pad 170 on the first insulating pattern structure 160 and contacting an upper surface of the first through-electrode structure 120. In the following description, in each of substrates, the first surface may correspond to a lower surface, and the second surface may correspond to an upper surface.

The first substrate 110 may include, for example, a semiconductor material such as silicon, germanium, silicon-germanium, or a III-V group compound semiconductor such as gallium phosphide GaP, gallium arsenide GaAs, or gallium antimonide GaSb. In some example embodiments, the first substrate 110 may be a silicon-on-insulator SOI substrate or a germanium-on-insulator GOI substrate.

A circuit device such as a logic device may be formed under the first surface 112 of the first substrate 110. The circuit device may include a plurality of circuit patterns.

The first insulating interlayer 130 may cover the circuit patterns. A first wiring structure 135 may be disposed in the first insulating interlayer 130. The first wiring structure 135 may include, for example, wirings, vias, contact plugs, etc., but is simply illustrated as one structure in FIG. 1 to avoid complexity of the drawing.

The first insulating interlayer 130 may include, for example, silicon oxide, or a low-k material such as an oxide doped with carbon or fluorine. The wirings, the vias and the contact plugs, etc. may include, for example, conductive materials such as a metal, a metal nitride, a metal silicide, etc.

The first conductive pad 140 may be disposed under the first insulating interlayer 130, and the first conductive pad 140 may contact the first wiring structure 135. The first conductive pad 140 may be electrically connected to the first wiring structure 135. In example embodiments, a plurality of the first conductive pads 140 may be spaced apart from each other in the horizontal direction.

In example embodiments, the first conductive pad 140 may include a first seed pattern and a first conductive pattern sequentially stacked in a downward direction from the first insulating interlayer 130. The first seed pattern may include, for example, titanium, and the first conductive pattern may include, for example, nickel, gold, etc.

The first external connecting member 150 may contact a lower surface of the first conductive pad 140. The first external connecting member 150 may include, for example, a solder ball. In some example embodiments, the first external connecting member may be omitted.

The first through-electrode structure 120 may pass through the first substrate 110 to extend in the vertical direction. A portion of the first through-electrode structure 120 that protrudes from the second surface 114 of the first substrate 110 may be surrounded by the first insulation pattern structure 160. A plurality of the first through-electrode structures 120 may be spaced apart from each other in the horizontal direction.

In example embodiments, the first through-electrode structure 120 may include a first through-electrode extending in the vertical direction, a first barrier pattern covering a sidewall of the first through-electrode, and a first sidewall insulation pattern covering an outer sidewall of the first barrier pattern.

The first through-electrode may include a metal such as copper, aluminum, or the like, the first barrier pattern may include a metal nitride such as titanium nitride, tantalum nitride, or the like, and the first sidewall insulation pattern may include an oxide such as silicon oxide, or an insulating nitride such as silicon nitride.

In example embodiments, the first through-electrode structure 120 may contact the first wiring structure 135 by penetrating the first insulation pattern structure 160 and the first substrate 110. The first through-electrode structure 120 may be electrically connected to the first conductive pad 140 via the first wiring structure 135.

In example embodiments, the first insulation pattern structure 160 may include a plurality of insulation patterns stacked in the vertical direction on the second surface 114 of the first substrate 110. For example, the first insulation pattern structure 160 may include a first insulation pattern including an oxide such as silicon oxide and a second insulation pattern including an insulating nitride such as silicon nitride.

The second conductive pad 170 may be electrically connected to the first conductive pad 140 via the first through-electrode structure 120 and the first wiring structure 135. In example embodiments, a plurality of second conductive pads 170 may be spaced apart from each other in the horizontal direction. In example embodiments, the second conductive pad 170 may include a second seed pattern and a second conductive pattern sequentially stacked in upward direction from the first insulation pattern structure 160. The second seed pattern may include, for example, titanium, and the second conductive pattern may include, for example, nickel, gold, etc.

A second semiconductor chip 200 may be disposed on the first semiconductor chip 100. The second semiconductor chip 200 may include a second substrate 210 having a first surface 212 and a second surface 214 being opposite to each other in the vertical direction, a second through-electrode structure 220 passing through the second substrate 210, a second insulating interlayer 230 sequentially stacked in the vertical direction under the first surface 212 of the second substrate 210, a third conductive pad 240 disposed under the second insulating interlayer 230, a protective pad 245 disposed under the second insulating interlayer 230 at an edge portion of the second surface 214 of the second substrate 210, a second insulation pattern structure 260 on the second surface 214 of the second substrate 210, and a fourth conductive pad 270 on the second insulation pattern structure 260 and contacting an upper surface of the second through-electrode structure 220. A first conductive connecting member 250 may be disposed between the second conductive pad 170 of the first semiconductor chip 100 and the third conductive pad 240 of the second semiconductor chip 200.

The second substrate 210 may include, for example, a semiconductor material such as silicon, germanium, silicon-germanium, or a III-V group compound semiconductor such as gallium phosphide GaP, gallium arsenide GaAs, gallium antimonide GaSb, or the like. In some example embodiments, the second substrate 210 may be a silicon-on-insulator SOI substrate or a germanium-on-insulator GOI substrate.

A volatile memory device such as a DRAM device, an SRAM device, or a nonvolatile memory device such as a flash memory device, an EEPROM device, etc., may be formed under the first surface 212 of the second substrate 210. The memory device may include a plurality of circuit patterns.

A second wiring structure 235 may be positioned in the second insulating interlayer 230. The second wiring structure 235 may include, for example, wirings, vias, contact plugs, etc., but is simply illustrated as one structure in FIG. 1 to avoid complexity of the drawing.

The second insulating interlayer 230 may include, for example, silicon oxide, or a low-k material such as an oxide doped with carbon or fluorine. The wirings, the vias, and the contact plugs, etc. may include, for example, conductive materials such as a metal, a metal nitride, a metal silicide, etc.

The third conductive pad 240 may be formed under the second insulating interlayer 230, and the third conductive pad 240 may contact the second wiring structure 235. The third conductive pad 240 may be electrically connected to the second wiring structure 235. In example embodiments, a plurality of the third conductive pads 240 may be spaced apart from each other in the horizontal direction.

The third conductive pad 240 may include a metal. In example embodiments, the third conductive pad 240 may include a third seed pattern and a third conductive pattern that are sequentially stacked in a downward direction from the second insulating interlayer 230. The third seed pattern may include, for example, titanium, and the third conductive patterns may include, for example, nickel, gold, etc.

The protection pad 245 may be formed under the second insulating interlayer 230, and the protection pad 245 may not contact the second wiring structure 235. The protection pad 245 may not be electrically connected to the second through-electrode structures 220.

The protection pad 245 may be provided to prevent from damages of the circuit patterns on the first surface 212 of the second substrate 210, in irradiating a laser beam. A plurality of protection pads 245 may be arranged along an edge of the first surface 212 of the second substrate 210. That is, the protection pads 245 may surround the edge of the lower portion of the second semiconductor chip 200.

In example embodiments, an edge of the protection pad 245 may be disposed to coincide with the edge of the first surface 212 of the second substrate 210. In some example embodiments, the edge of the protection pad 245 may be positioned inward from the edge of the first surface 212 of the second substrate 210.

In example embodiments, as shown in FIG. 2, the protection pad 245 may have a ring shape extending along an edge of a lower portion of the second semiconductor chip 200. The protection pad 245 may surround the third conductive pads 240. In FIG. 2, although the protection pad 245 is illustrated as having a single ring shape extending along the edge of the lower portion of the second semiconductor chip 200, the concept of the present invention is not limited thereto, and the protection pad may have a plurality of ring shapes being spaced apart from each other.

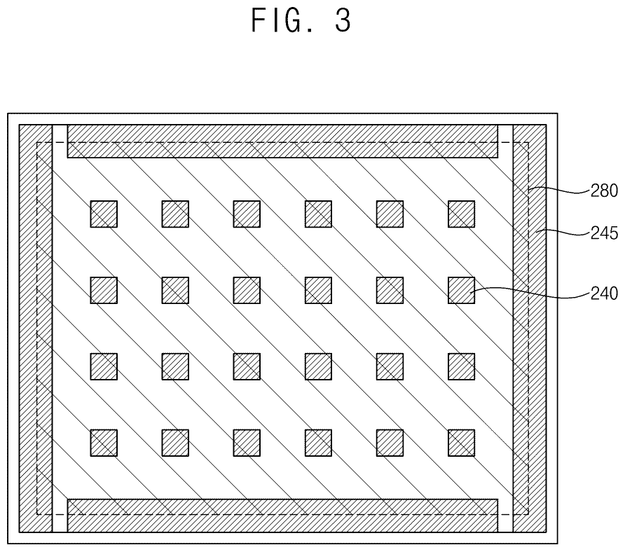

In example embodiments, as shown in FIG. 3, the protection pad 245 may have a bar shape extending along the edge of the lower portion of the second semiconductor chip 200. At least one protection pad 245 having bar shape may be arranged adjacent to each side of the edge of the lower portion of the second semiconductor chip 200. In FIG. 3, although each protection pad 245 is disposed in one row at each side of the edge of the lower portion of the second semiconductor chip 200, the concept of the present invention is not limited thereto, and each protection pad 245 may be disposed in a plurality of rows at each side of the edge of the lower portion of the second semiconductor chip 200.

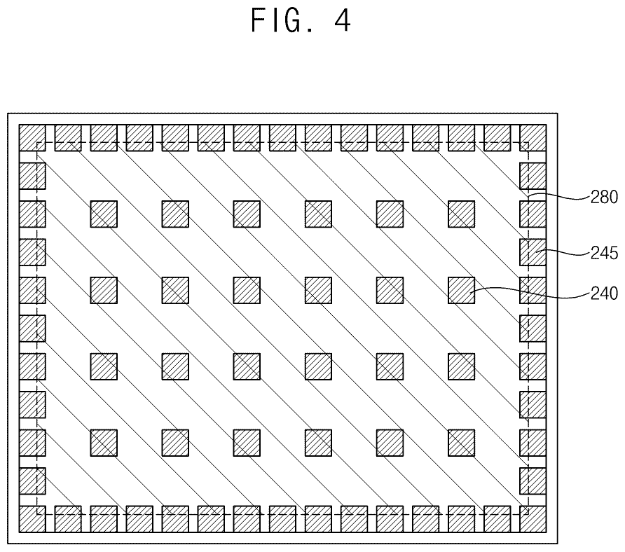

In example embodiments, as shown in FIG. 4, the protection pad 245 may have a rectangle shape arranged along the edge of the lower portion of the second semiconductor chip 200. A plurality of protection pads 245 may be spaced apart from each other, and may be adjacent to each side of the edge of the lower portion of the second semiconductor chip 200. The rectangle shape may be, for example, a rectangle or a square. In FIG. 4 each protection pad 245 may be disposed in a row at each side of the edge of the lower portion of the second semiconductor chip 200, but the concept of the present invention is not limited thereto, and each protection pad 245 may be disposed in a plurality of rows at each side of the edge of the lower portion of the second semiconductor chip 200.

The protection pad 245 may include a metal. In example embodiments, the protection pad 245 and the third conductive pad 240 may be formed by the same process, and thus, the protection pad 245 and the third conductive pad 240 may include the same material.

The first conductive connecting member 250 may contact an upper surface of the second conductive pad 170 and a lower surface of the third conductive pad 240. The first conductive connecting member 250 may be, for example, a conductive bump. The first conductive connecting member 250 may include, for example, a metal such as tin (Sn), or solder. The first conductive connecting member 250 may be interposed between the second conductive pad 170 included in an upper portion of the first semiconductor chip 100 and the third conductive pad 240 included in the lower portion of the second semiconductor chip 200, so that the first and second semiconductor chips 100 and 200 may be bonded to each other.

The second through-electrode structure 220 may pass through the second substrate 210 to extend in the vertical direction. The second through-electrode structure 220 may protrude from the second surface 214 of the second substrate 210, and a protruding portion of the second through-electrode structure 220 may be surrounded by the second insulation pattern structure 260. A plurality of the second through-electrode structures 220 may be spaced apart from each other in the horizontal direction. In example embodiments, the second through-electrode structure 220 may include a second through-electrode extending in the vertical direction, a second barrier pattern covering a sidewall of the second through-electrode, and a second sidewall insulation pattern covering an outer sidewall of the second barrier pattern.

The second through-electrode may include a metal, such as copper, aluminum, or the like. The second barrier pattern may include a metal nitride, such as titanium nitride, tantalum nitride, or the like. The second insulation pattern may include an oxide, such as silicon oxide, or an insulating nitride, such as silicon nitride.

In example embodiments, the second through-electrode structure 220 may contact a second wiring structure 235 by penetrating the second insulation pattern structure 260 and the second substrate 210, and the second through-electrode structure 220 may be electrically connected to a third conductive pad 240 by the second wiring structure 235.

The second insulation pattern structure 260 may be formed on the second surface 214 of the second substrate 210, and the second insulation pattern structure 260 may surround an upper portion of the second through-electrode structure 220.

In example embodiments, the second insulation pattern structure 260 may include a plurality of insulation patterns stacked in the vertical direction on the second surface 214 of the second substrate 210. For example, the second insulation pattern structure 260 may include a third insulation pattern including an oxide such as silicon oxide and a fourth insulation pattern including an insulating nitride such as silicon nitride.

The fourth conductive pad 270 may be electrically connected to the third conductive pad 240 via the second through-electrode structure 220 and the second wiring structure 235. In example embodiments, a plurality of fourth conductive pads 270 may be spaced apart from each other in the horizontal direction.

In example embodiments, the fourth conductive pad 270 may include a fourth seed pattern and a fourth conductive pattern sequentially stacked in an upward direction from the second insulation pattern structure 260. The fourth seed pattern may include, for example, titanium, and the fourth conductive pattern may include, for example, nickel, gold, etc.

The third to fifth semiconductor chips 300, 400 and 500 may be sequentially stacked in the vertical direction on the second semiconductor chip 200.

Except for the fifth semiconductor chip, which is the semiconductor chip located at the top of the stack of semiconductor chips, the third and fourth semiconductor chips may have structures that are the same or similar to a structure of the second semiconductor chip 200. The third and fourth semiconductor chips 300 and 400 may include elements the same as elements included in the second semiconductor chip 200. In example embodiments, the semiconductor chips between lowermost semiconductor chip and the uppermost semiconductor chip may be substantially identical chips.

Particularly, each of the third and fourth semiconductor chips 300 and 400 may include the second substrate 210, the second through-electrode structure 220 passing through the second substrate 210, the second insulating interlayer 230 under the first surface 212 of the second substrate 210, the third conductive pad 240 under the second insulating interlayer 230, the protective pad 245 disposed under the second insulating interlayer 230 at the edge portion of the second surface 214 of the second substrate 210, the second insulation pattern structure 260 on the second surface 214 of the second substrate 210, and the fourth conductive pad 270 on the second insulation pattern structure 260 and contacting the upper surface of the second through-electrode structure 220.

The fifth semiconductor chip 500 located at the top may have a structure that is the same or similar to the structure of the second semiconductor chip 200, except that it may not include the through-electrode structure passing through the second substrate 210 and the second insulation pattern structure 260. In the fifth semiconductor chip 500, the same element as the second semiconductor chip 200 is given the same reference numeral as the second semiconductor chip 200.

The second conductive connecting member 350 may be interposed between the fourth conductive pad 270 included in an upper portion of the second semiconductor chip 200 and the third conductive pad 240 included in a lower portion of the third semiconductor chip 300, and the second and third semiconductor chips 200 and 300 may be bonded to each other through the second conductive connecting member 350.

The third conductive connecting member 450 may be interposed between the fourth conductive pad 270 included in an upper portion of the third semiconductor chip 300 and the third conductive pad 240 included in a lower portion of the fourth semiconductor chip 400, and the third and fourth semiconductor chips 300 and 400 may be bonded to each other through the third conductive connecting member 450.

The fourth conductive connecting member 550 may be interposed between the fourth conductive pad 270 included in an upper portion of the fourth semiconductor chip 400 and the third conductive pad 240 included in a lower portion of the fifth semiconductor chip 500, and the fourth and fifth semiconductor chips 400 and 500 may be bonded to each other through the fourth conductive connecting member 550.

The first to fourth adhesive layers 280, 380, 480 and 580 may be interposed between the first to fifth semiconductor chips 100, 200, 300, 400 and 500 in the vertical direction, respectively, and the first to fifth semiconductor chips 100, 200, 300, 400 and 500 may be boned to each other through the first to fourth adhesive layers 280, 380, 480 and 580, respectively.

The first adhesive layer 280 may fill a gap between the first semiconductor chip 100 and the second semiconductor chip 200 in the vertical direction. The first adhesive layer 280 may contact the upper surface of the first semiconductor chip 100 and a lower surface of the second semiconductor chip 200. The first adhesive layer 280 may surround the second conductive pads 170 of the first semiconductor chip 100, the third conductive pads 240 of the second semiconductor chip 200, and the first conductive connecting members 250 between the first and second semiconductor chips 200.

An edge of the first adhesive layer 280 may be positioned inward from a sidewall of the second semiconductor chip 200. For example, the edge of the first adhesive layer 280 may be at the end of the first adhesive layer 280 and there may be a horizontal gap between the edge of the first adhesive layer 280 and a lower edge of the sidewall of the second semiconductor chip 200. In FIGS. 2 to 4, the dotted line shown in the figures may correspond to the edge of the first adhesive layer 280.

Therefore, an edge portion of the lower surface of the second semiconductor chip 200 (e.g., the area between the upper edge of the sidewall and the edge of the first adhesive layer 280) may not be covered by the first adhesive layer 280. The edge portion of the lower surface of the second semiconductor chip 200 may be exposed by the first adhesive layer 280 (e.g., the first adhesive layer 280 may not cover the edge portion). The edge portion of the lower surface of the second semiconductor chip 200 may be a portion from an end of the lower surface of the second semiconductor chip (e.g., an edge where the lower surface transitions to a side surface) to an interior position a certain distance of the side surface of the second semiconductor chip.

The first adhesive layer 280 may not have a portion protruding outward beyond an edge of the second semiconductor chip 200 (e.g., the first adhesive layer 280 may not protrude horizontally beyond the side surface of the second semiconductor chip 200). The first adhesive layer 280 may not have a portion protruding outward from an edge of the first semiconductor chip 100 (e.g., the first adhesive layer 280 may not protrude horizontally beyond the side surface of the first semiconductor chip 100). Accordingly, the first adhesive layer 280 may not be attached on the sidewall of the second semiconductor chip 200.

The edge of the first adhesive layer 280 may be positioned outward from an outermost first conductive connecting member 250 between the first and second semiconductor chips 100 and 200. The first adhesive layer 280 may surround all of the first conductive connecting members 250 interposed between the first and second semiconductor chips 100 and 200. A first edge gap 285 between the first and second semiconductor chips 100 and 200 may be defined between a sidewall of the first adhesive layer 280 and the edge of the lower surface of the second semiconductor chip 200. The first edge gap 285 may be disposed between the first and second semiconductor chips 100 and 200. At least a portion of the protective pad 245 may be exposed by the first edge gap 285 (e.g., at least a portion of the protective pad 245 is disposed in the first edge gap 285 and not covered by the first adhesive layer 280).

In example embodiments, the edge of the first adhesive layer 280 may contact at least a portion of the protective pad 245. In example embodiments, the first adhesive layer 280 may extend to overlap at least a portion of the protective pad 245.

The second adhesive layer 380 may fill a gap between the second semiconductor chip 200 and the third semiconductor chip 300 in the vertical direction. The second adhesive layer 380 may contact an upper surface of the second semiconductor chip 200 and a lower surface of the third semiconductor chip 300. The second adhesive layer 380 may surround the fourth conductive pads 270 of the second semiconductor chip 200, the third conductive pads 240 of the third semiconductor chip 300, and the second conductive connecting members 350 between the second and third semiconductor chips 200 and 300.

An edge of the second adhesive layer 380 may be positioned inward from the sidewall of the second semiconductor chip 200 and a sidewall of the third semiconductor chip 300. For example, the edge of the second adhesive layer 380 may be at an end of the second adhesive layer 380 and there may be a horizontal gap between the edge of the second adhesive layer 380 and an upper edge of the sidewall of the second semiconductor chip 200 and the lower edge of the sidewall of the third semiconductor chip 300. Accordingly, the upper surface of the second semiconductor chip 200 adjacent to the edge of the second semiconductor chip 200 and the lower surface of the third semiconductor chip 300 adjacent to the edge of the third semiconductor chip 300 may not be covered by the second adhesive layer 380. The upper surface of the second semiconductor chip 200 adjacent to the edge of the second semiconductor chip 200 and the lower surface of the third semiconductor chip 300 adjacent to the edge of the third semiconductor chip 300 may be exposed by the second adhesive layer 380. The second adhesive layer 380 may not have a portion protruding outward beyond the edges of the second and third semiconductor chips 300. Accordingly, the second adhesive layer 380 may not be attached on the sidewall of the second semiconductor chip 200 and the sidewall of the third semiconductor chip 300.

The edge of the second adhesive layer 380 may be positioned outward from an outermost second conductive connecting member 350 between the second and third semiconductor chips 200 and 300. The second adhesive layer 380 may surround all of the second conductive connecting members 350 interposed between the second and third semiconductor chips 200 and 300. A second edge gap 385 between the second and third semiconductor chips 200 and 300 may be defined by a sidewall of the second adhesive layer 380, the edge of the upper surface of the second semiconductor chip 200, and the edge of the lower surface of the third semiconductor chip 300. The second edge gap 385 may be disposed between the second and third semiconductor chips 200 and 300. At least a portion of the protective pad 245 may be exposed by the second edge gap 385 (e.g., at least a portion of the protective pad 245 is disposed in the second edge gap 385 and not covered by the second adhesive layer).

The third adhesive layer 480 may fill a gap between the third semiconductor chip 300 and the fourth semiconductor chip 400 in the vertical direction. The third adhesive layer 480 may contact an upper surface of the third semiconductor chip 300 and a lower surface of the fourth semiconductor chip 400. The third adhesive layer 480 may surround the fourth conductive pads 270 of the third semiconductor chip 300, the third conductive pads 240 of the fourth semiconductor chip 400, and the third conductive connecting members 450 between the third and fourth semiconductor chips 300 and 400.

An edge of the third adhesive layer 480 may be positioned inward from the sidewall of the third semiconductor chip 300 and a sidewall of the fourth semiconductor chip 400. For example, the edge of the third adhesive layer 480 may be at an end of the third adhesive layer 480 and there may be a horizontal gap between the edge of the third adhesive layer 480 and an upper edge of the sidewall of the third semiconductor chip 300 and the lower edge of the sidewall of the fourth semiconductor chip 400. Accordingly, the upper surface of the third semiconductor chip 300 adjacent to the edge of the third semiconductor chip 300 and the lower surface of the fourth semiconductor chip 400 adjacent to the edge of the fourth semiconductor chip 400 may not be covered by the third adhesive layer 480. The upper surface of the third semiconductor chip 300 adjacent to the edge of the third semiconductor chip 300 and the lower surface of the fourth semiconductor chip 400 adjacent to the edge of the fourth semiconductor chip 400 may be exposed by the third adhesive layer 480. The third adhesive layer 480 may not have a portion protruding outward beyond the edges of the third and fourth semiconductor chips 300 and 400. Accordingly, the third adhesive layer 480 may not be attached on the sidewall of the third semiconductor chip 300 and the sidewall of the fourth semiconductor chip 400.

The edge of the third adhesive layer 480 may be positioned outward from an outermost third conductive connecting member 450 between the third and fourth semiconductor chips 300 and 400. The third adhesive layer 480 may surround all of the third conductive connecting members 450 interposed between the third and fourth semiconductor chips 300 and 400. A third edge gap 485 between the third and fourth semiconductor chips 300 and 400 may be defined by a sidewall of the third adhesive layer 480, the edge of the upper surface of the third semiconductor chip 300, and the edge of the lower surface of the fourth semiconductor chip 400. The third edge gap 485 may be disposed between the third and fourth semiconductor chips 300 and 400. At least a portion of the protective pad 245 may be exposed by the third edge gap 485 (e.g., at least a portion of the protective pad 245 is disposed in the third edge gap 485 and not covered by the third adhesive layer 480).

The fourth adhesive layer 580 may fill a gap between the fourth semiconductor chip 400 and the fifth semiconductor chip 500 in the vertical direction. The fourth adhesive layer 580 may contact an upper surface of the fourth semiconductor chip 400 and a lower surface of the fifth semiconductor chip 500. The fourth adhesive layer 580 may surround the fourth conductive pads 270 of the fourth semiconductor chip 400, the third conductive pads 240 of the fifth semiconductor chip 500, and the fourth conductive connecting members 550 between the fourth and fifth semiconductor chips 400 and 500.

The edge of the fourth adhesive layer 580 may be positioned inward from the sidewall of the fourth semiconductor chip 400 and the sidewall of the fifth semiconductor chip 500. For example, the edge of the fourth adhesive layer 580 may be at an end of the fourth adhesive layer 580 and there may be a horizontal gap between the edge of the fourth adhesive layer 580 and an upper edge of the sidewall of the fourth semiconductor chip 400 and the lower edge of the sidewall of the fifth semiconductor chip 500. Accordingly, the upper surface of the fourth semiconductor chip 400 adjacent to the edge of the fourth semiconductor chip 400 and the lower surface of the fifth semiconductor chip 500 adjacent to the edge of the fifth semiconductor chip 500 may not be covered by the fourth adhesive layer 580. The upper surface of the fourth semiconductor chip 400 adjacent to the edge of the fourth semiconductor chip 400 and the lower surface of the fifth semiconductor chip 500 adjacent to the edge of the fifth semiconductor chip 500 may be exposed by the fourth adhesive layer 580. The fourth adhesive layer 580 may not have a portion protruding beyond the edge of the fourth and fifth semiconductor chips 400 and 500. In addition, the fourth adhesive layer 580 may not be attached to the sidewall of the fourth semiconductor chip 400 and the sidewall of the fifth semiconductor chip 500. The fourth adhesive layer 580 may surround all of the fourth conductive connecting members 550 interposed between the fourth and fifth semiconductor chips 400 and 500. A fourth edge gap 585 between the fourth and fifth semiconductor chips 400 and 500 may be defined by the sidewall of the fourth adhesive layer 580, the edge of the upper surface of the fourth semiconductor chip 400, and the edge of the lower surface of the fifth semiconductor chip 500. The fourth edge gap 585 may expose at least a portion of the protective pad 245 (e.g., at least a portion of the protective pad 245 is disposed in the fourth edge gap 585 and not covered by the fourth adhesive layer 580).

In example embodiments, as illustrated in FIG. 1, the sidewalls of the first to fourth adhesive layers 280, 380, 480 and 580 may be aligned in the vertical direction. For example, the sidewalls of the first to fourth adhesive layers 280, 380, 480 and 580 may be arranged the same in the vertical direction. Accordingly, ends of the first to fourth edge gaps 285, 385, 485 and 585 may be aligned in the vertical direction.

In some example embodiments, as illustrated in FIG. 5, the sidewalls of the first to fourth adhesive layers 280, 380, 480 and 580 may not be aligned in the vertical direction. For example, at least one of the sidewalls of the first to fourth adhesive layers 280, 380, 480, and 580 may not be aligned with the other sidewalls of the first to fourth adhesive layers 280, 380, 480, and 580 in the vertical direction. Accordingly, ends of the first to fourth edge gaps 285, 385, 485 and 585 may not be aligned in the vertical direction.

The first to fourth adhesive layers 280, 380, 480 and 580 may include the same material. In example embodiments, the first to fourth adhesive layers 280, 380, 480 and 580 may include a non-conductive film (NCF). The first to fourth adhesive layers 280, 380, 480 and 580 may include, for example, epoxy resin, UV resin, polyurethane resin, silicone resin, silica filler, thermosetting material, thermoplastic material, UV treatment material, etc.

The molding member 600 may be disposed on the first semiconductor chip 100, and may cover the sidewalls of the second to fifth semiconductor chips 200, 300, 400 and 500 and the sidewalls of the first to fourth adhesive layers 280, 380, 480 and 580.

The molding member 600 may fill the first to fourth edge gaps 285, 385, 485 and 585. The molding member 600 may contact the sidewall of the first adhesive layer 280 defining the first edge gap 285, the upper surface of the first semiconductor chip 100, and the lower surface of the second semiconductor chip 200, respectively. The molding member 600 may contact the sidewall of the second adhesive layer 380 defining the second edge gap 385, the upper surface of the second semiconductor chip 200, and the lower surface of the third semiconductor chip 300, respectively. The molding member 600 may contact the sidewall of the third adhesive layer 480 defining the third edge gap 385, the upper surface of the third semiconductor chip 300, and the lower surface of the fourth semiconductor chip 400, respectively. The molding member 600 may contact the sidewall of the fourth adhesive layer 580 defining the fourth edge gap 485, the upper surface of the fourth semiconductor chip 400, and the lower surface of the fifth semiconductor chip 500, respectively.

In this way, the first to fourth adhesive layers 280, 380, 480 and 580 may fill first portions within the gaps between the first to fifth semiconductor chips 100, 200, 300, 400 and 500 in the vertical direction. In addition, the molding member 600 may fill second portions adjacent to the edge of the gaps between the first to fifth semiconductor chips 100, 200, 300, 400 and 500 in the vertical direction. In addition, the molding member 600 may contact the sidewalls of the first to fourth adhesive layers 280, 380, 480 and 580. The molding member 600 may contact at least a portion of the protective pads 245 included in the first to fifth semiconductor chips 100, 200, 300, 400 and 500.

In example embodiments, the molding member 600 may cover the sidewalls of the second to fifth semiconductor chips 200, 300, 400 and 500 and the upper portion of the fifth semiconductor chip 500. In some example embodiments, the molding member 600 may cover the sidewalls of the second to fifth semiconductor chips 200, 300, 400 and 500, and may not cover the upper portion of the fifth semiconductor chip 500. In this case, the upper surface of the molding member 600 may be substantially coplanar with the upper surface of the fifth semiconductor chip 500.

The molding member 600 may include, for example, an epoxy molding compound EMC. The molding member 600 and the adhesive layers 280, 380, 480 and 580 may be different materials to each other.

The first to fifth semiconductor chips 100, 200, 300, 400 and 500 may be electrically connected to each other by the through-electrode structures 120 and 220, the wiring structures 135 and 235, the conductive pads 140, 170, 240 and 270, and the conductive connecting members 250, 350, 450 and 550 included in the first to fifth semiconductor chips 100, 200, 300, 400 and 500. Therefore, the first to fifth semiconductor chips 100, 200, 300, 400 and 500 may communicate electrical signals such as data signals and control signals. In addition, the first conductive pad 140 included in the first semiconductor chip 100 may communicate electrical signals with an external device through the first external connecting member 150.

In the semiconductor package, each of the first to fourth conductive connecting members 250, 350, 450 and 550 may transit electrical signals between the first to fifth semiconductor chips 100, 200, 300, 400 and 500 arranged at upper and lower levels.

As described above, the substrate included in each of the first to fifth semiconductor chips 100, 200, 300, 400 and 500 may include, for example, silicon, and each of the first to fourth adhesive layers 280, 380, 480 and 580 interposed between the first to fifth semiconductor chips 100, 200, 300, 400 and 500 may include, for example, NCF. The molding member 600 that may be disposed on the first semiconductor chip 100 and may cover the sidewalls of the second to fifth semiconductor chips 200, 300, 400 and 500 and the sidewalls of the first to fourth adhesive layers 280, 380, 480 and 580 may include, for example, EMC.

The materials have different coefficients of thermal expansion CTE, and in particular, the NCF may have a coefficient of thermal expansion greater than a coefficient of thermal expansion of EMC or silicon. The NCF may have a coefficient of thermal expansion of approximately 3.47×10⁻⁵. When the semiconductor package is exposed to high temperature, the NCF may expand more than the silicon or EMC, and thus, stress may be concentrated at interfaces between each of the first to fifth semiconductor chips 100, 200, 300, 400 and 500 and each of the first to fourth adhesive layers 280, 380, 480 and 580 and interfaces between each of the first to fourth adhesive layers 280, 380, 480 and 580 and the molding member 600. In particular, there is a risk of delamination at the interface of NCF and silicon or EMC, such as at the interfaces between each of the first to fourth adhesive layers 280, 380, 480 and 580 and the molding member 600.

If adhesive layers were to protrude beyond the edges of semiconductor chips in a semiconductor package, adhesive layer fillets may be created. Such adhesive layer fillets may be attached on the sidewalls of the semiconductor chips. In this case, since the molding member is also attached on the adhesive layer fillet, an area of the interface between a material of the adhesive layers and the adhesive layer fillet and a material of the molding member may be greatly increased, and a surface of the interfaces may be irregular. For example, the area of the interface between the material of the adhesive layers and the adhesive layer fillet and the material of the molding member may be similar to an entire area of a sidewall of the semiconductor chips and gaps between the semiconductor chips. When the area of the interface between the adhesive layers and the adhesive layer fillet and the molding member is increased, the delamination phenomenon may occur frequently at the interface between the adhesive layers and the molding member. In addition, when the adhesive layer fillets are increased, a stress in a mounting the semiconductor package may increase. Therefore, reliability may be impacted, and a failure of the semiconductor package may occur.

In example embodiments, the first to fourth adhesive layers 280, 380, 480 and 580 may not protrude beyond the edges of the second to fifth semiconductor chips 200, 300, 400 and 500, and the first to fourth adhesive layers 280, 380, 480 and 580 may not be attached on the sidewalls of the second to fifth semiconductor chips 200, 300, 400 and 500. Therefore, adhesive layer fillets may not be formed on the sidewalls of the second to fifth semiconductor chips 200, 300, 400 and 500. The area of the interface between the first to fourth adhesive layers 280, 380, 480 and 580 and the molding member 600 may be decreased relative to when adhesive layers extend beyond the edges of the semiconductor chips. For example, the area of the interface between the first to fourth adhesive layers 280, 380, 480 and 580 and the molding member 600 may be the same as the area of the sidewalls of the first to fourth adhesive layers 280, 380, 480 and 580 disposed between the first to fifth semiconductor chips 100, 200, 300, 400 and 500. In this way, when the area of the interface between the first to fourth adhesive layers 280, 380, 480 and 580 and the molding member 600 is decreased, the delamination phenomenon at the interface between the first to fourth adhesive layers 280, 380, 480 and 580 and the molding member 600 may be decreased. In addition, since the first to fourth adhesive layers 280, 380, 480 and 580 may not have portions protruding beyond the edges of the second to fifth semiconductor chips 200, 300, 400 and 500, the stress in the mounting of the semiconductor package may be decreased. Therefore, the reliability may be increased and the frequency of failure of the semiconductor package may be decreased.

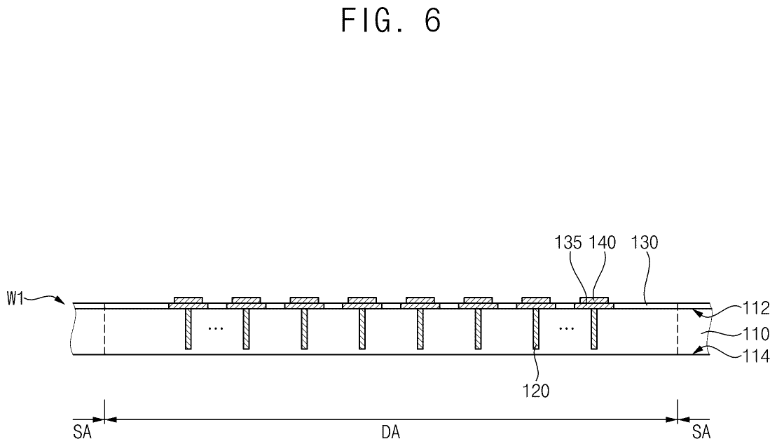

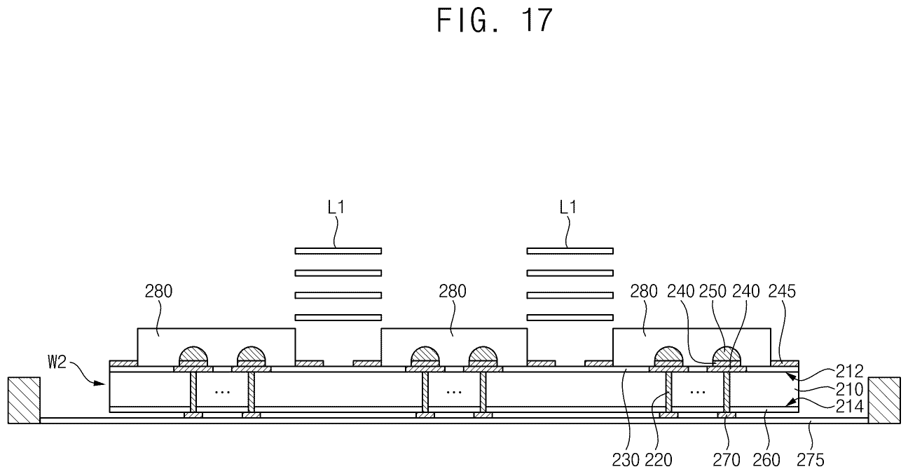

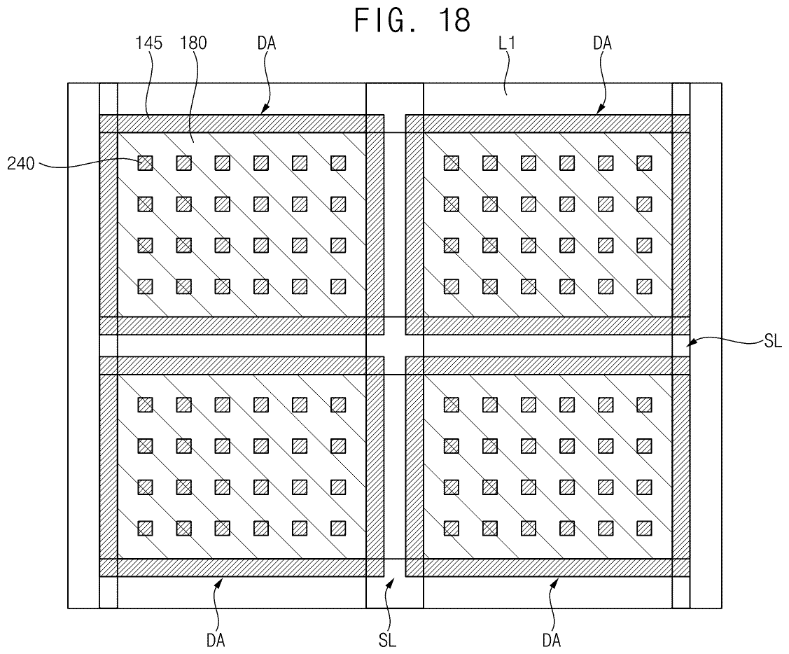

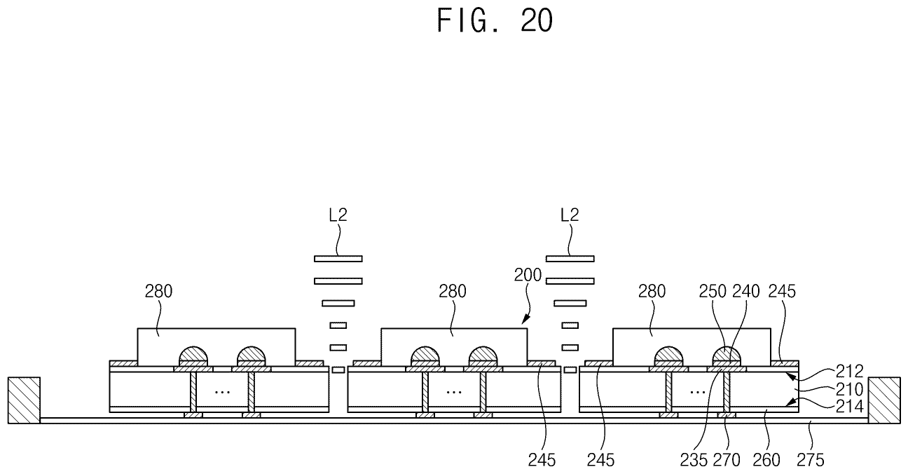

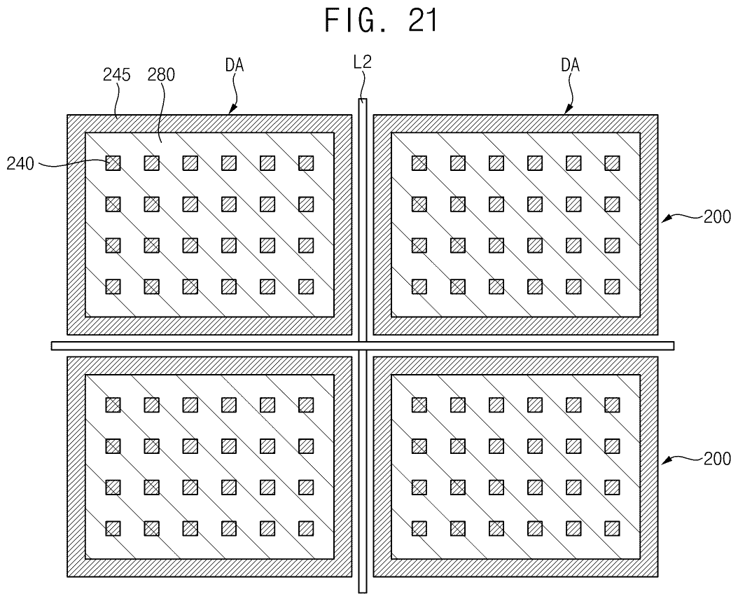

FIGS. 6 to 25 are cross-sectional views and plan views illustrating a method of manufacturing a semiconductor package according to example embodiments.

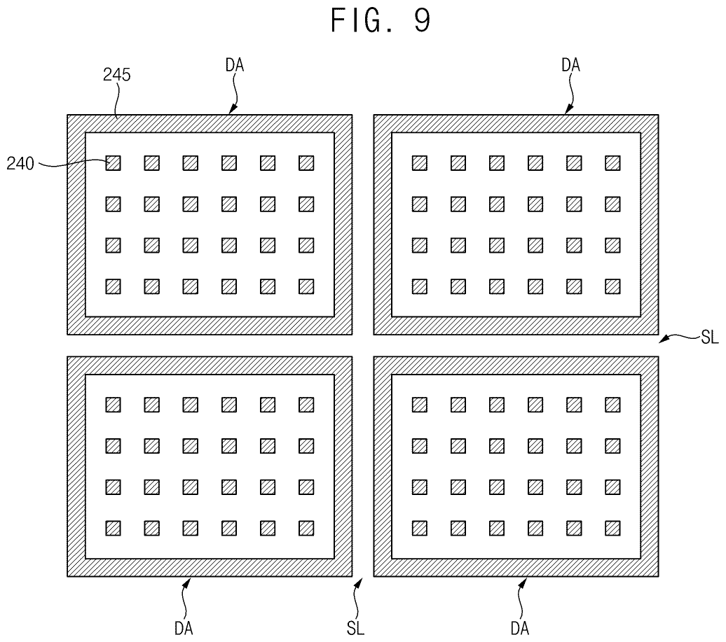

FIGS. 6 to 8, FIGS. 12 to 17, FIGS. 19, 20, and FIGS. 22 to 25 are cross-sectional views, and FIGS. 9 to 11, FIG. 18 and FIG. 21 are plan views.

Referring to FIG. 6, a first wafer W1 may be provided.

In example embodiments, the first wafer W1 may include a first substrate 110 having a first surface 112 and a second surface 114 that face each other in the vertical direction. The first wafer W1 may include a plurality of die areas DA, and a scribe lane area SA surrounding each of the die areas DA.

Within the die area (DA), a circuit device may be formed on the first surface 112 of the first substrate 110. In example embodiments, the circuit device may include a logic device. The circuit device may include a plurality of circuit patterns.

A first through-electrode structure 120 may be formed that extends from the first surface 112 of the first substrate 110 to an inside of the first substrate 110 in the vertical direction. In example embodiments, a plurality of the first through-electrode structures 120 may be formed to be spaced apart from each other in a horizontal direction within each of the die areas DA of the first wafer W1.

A first insulating interlayer 130 may be formed on the circuit patterns, and a first wiring structure 135 may be formed in the first insulating interlayer 130. The first wiring structure 135 may be electrically connected to the circuit patterns. The first wiring structure 135 may include, e.g., wirings, vias, contact plugs, etc. The first wiring structure 135 may be electrically connected to the first through-electrode structure 120.

A first conductive pad 140 may be formed to be electrically connected to the first wiring structure 135. In example embodiments, a plurality of the first conductive pads 140 may be formed to be spaced apart from each other in the horizontal direction.

In example embodiments, the first conductive pad 140 may be formed by the following processes.

A first seed layer may be formed on the first insulating interlayer 130, and a first photoresist pattern including first openings partially exposing the upper surface of the first seed layer may be formed on the first seed layer. Then, a first conductive pattern may be formed in the first opening by, for example, an electrolytic plating process or an electroless plating process. Thereafter, the first photoresist pattern may be removed by, for example, an ashing process and/or a stripping process to partially expose the first seed layer. An exposed portion of the first seed layer may be removed to form a first seed pattern under the first conductive pattern. Accordingly, a first conductive pad 140 including the first seed pattern and the first conductive patterns sequentially stacked in the vertical direction may be formed on the first wiring structure 135.

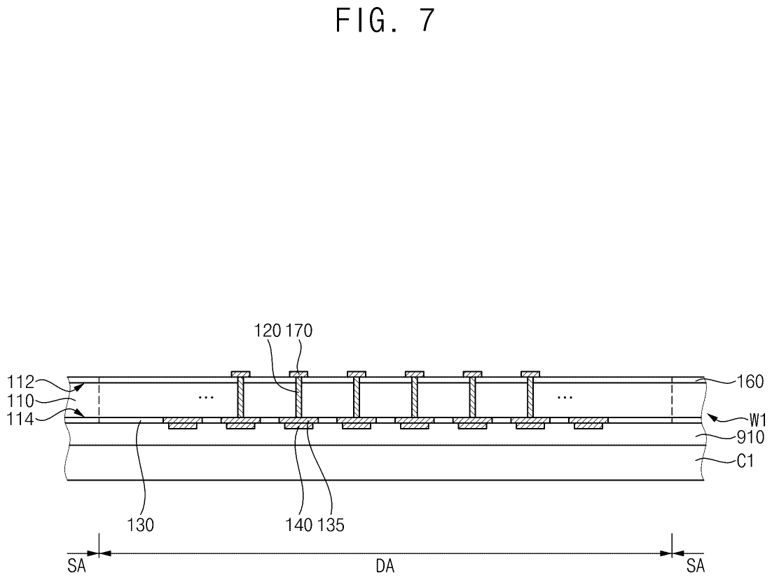

Referring to FIG. 7, a first temporary adhesive layer 910 may be attached on a first carrier substrate C1. The first temporary adhesive layer 910 may cover the first conductive pad 140 on the first wafer W1 and may contact an upper surface of the first insulating interlayer 130 on which a first wiring structure 135 is formed. Therefore, the first carrier substrate C1 may bond on the first wafer W1.

The first temporary adhesive layer 910 may include a material that may lose its adhesive strength by irradiating light such as ultraviolet UV light or by heating. In example embodiments, the first temporary adhesive layer 910 may include glue.

After turning over the first wafer W1, a portion adjacent to the second surface 114 of the first substrate 110 may be removed by, for example, a grinding process to expose an upper portion of the first through-electrode structure 120.

Thereafter, a first protective layer structure covering the first through-electrode structure 120 may be formed on the second surface 114 of the first substrate 110. A planarization process may be performed on the first protective layer structure until the upper surface of the first through-electrode structure 120 is exposed to form a first insulation pattern structure 160. In example embodiments, the planarization process may include a chemical mechanical polishing CMP process and/or an etch-back process.

In example embodiments, the first passivation layer structure may include a plurality of passivation layers sequentially stacked in the vertical direction, and during the planarization process, one(s) of the passivation layers may be removed and other one(s) of the passivation layers may remain.

Thereafter, a second conductive pad 170 may be formed on the first insulation pattern structure 160 and the first through-electrode structure 120. In example embodiments, a plurality of second conductive pads 170 may be spaced apart from each other along the horizontal direction. Each of the second conductive pads 170 may contact the upper surface of the first through-electrode structure 120, and thus the second conductive pad 170 and the first through-electrode structure 120 may be electrically connected to each other.

In example embodiments, the second conductive pad 170 may be formed by the following processes.

A second seed layer may be formed on the first insulation pattern structure 160 and the first through-electrode structure 120, and a second photoresist pattern including second openings that partially exposes the upper surface of the second seed layer may be formed on the second seed layer. Then, a second conductive pattern may be formed in the third opening by, for example, the electrolytic plating process or the electroless plating process.

Thereafter, the second photoresist pattern is removed by, for example, an ashing process and/or a stripping process to partially expose the second seed layer. An exposed portion of the second seed layer may be removed to form a second seed pattern under the second conductive pattern.

Accordingly, a second conductive pad 170 including the second seed pattern and the second conductive patterns sequentially stacked in the vertical direction can be formed on the first through-electrode structure 120.

By the above process, first semiconductor chips 100 may be formed in each of die areas DA of the first wafer W1.

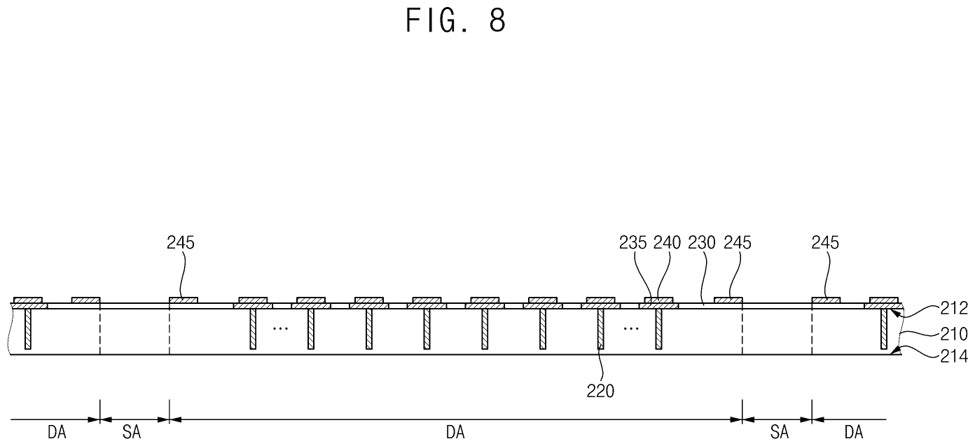

Referring to FIG. 8, a second wafer W2 may be provided.

In example embodiments, the second wafer W2 may include a second substrate 210 having a first surface 212 and a second surface 214 that face away from each other in the vertical direction. In addition, the second wafer W2 may include a plurality of die areas DA and a scribe lane area SA surrounding each of die areas DA. The scribe lane area SA may be cut by a subsequent sawing process, so that the second semiconductor chips formed in die areas DA may be singulated.

Within the die area DA, a circuit device may be formed on the first surface 212 of the second substrate 210. The circuit device may include a memory device. The circuit device may include a plurality of circuit patterns.

A second through-electrode structure 220 may be formed that extends from the first surface 212 of the second substrate 210 to the inside of the second substrate 210 in the vertical direction. In example embodiments, a plurality of second through-electrode structures 220 may be formed to be spaced apart from each other in the horizontal direction within each of die areas DA of the Second Wafer W2.

A second insulating interlayer 230 may be formed to cover the circuit patterns, and a second wiring structure 235 may be formed in the second insulating interlayer 230. The second wiring structure 235 may include, for example, wirings, vias, contact plugs, etc. In example embodiments, the uppermost surface of the second insulating interlayer 230 and the uppermost surface of the second wiring structure 235 may be coplanar with each other, and may be substantially flat. The uppermost surface of the second wiring structure 235 may be exposed by the second insulating interlayer 230. The second wiring structure 235 may be electrically connected to the second through-electrode structure 220.

A third conductive pad 240 may be formed on the second wiring structure 235, and may be electrically connected to the second wiring structure 235. In example embodiments, a plurality of the third conductive pads 240 may be formed be spaced apart from each other in the horizontal direction.

A protection pad 245 may be formed on the second insulating interlayer 230. The protection pad 245 may be disposed within the die area DA of the second wafer W2, and may be arranged along the edge portion of the die area DA. The protection pad 245 may not contact the second wiring structure 235. The protection pad 245 may be provided to prevent the circuit pattern arranged on the first surface 212 of the second substrate 210 from being damaged due to laser beam irradiation.

In example embodiments, as illustrated in FIG. 9, the protection pad 245 may have a ring shape extending along the edge of each die area DA of the second wafer W2. Accordingly, the protection pad 245 may be arranged to surround the third conductive pads 240.

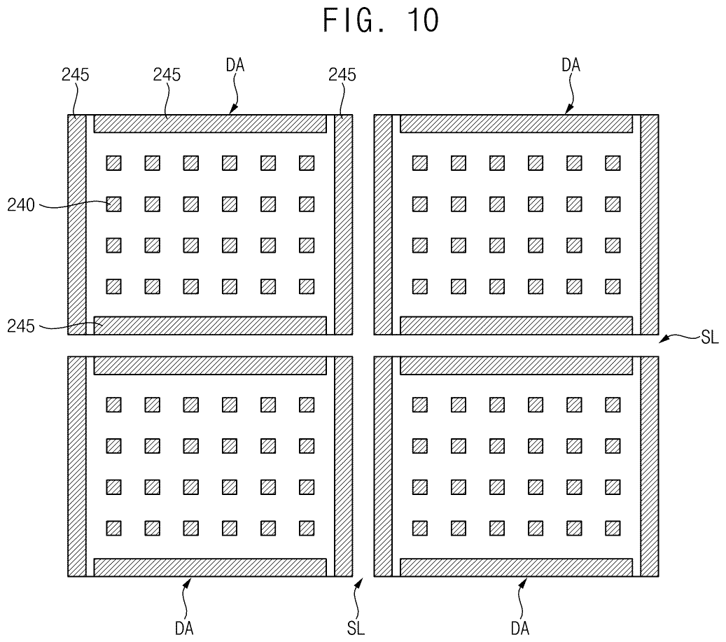

In example embodiments, as illustrated in FIG. 10, the protection pad 245 may have a bar shape. A plurality of the protection pads 245 may be arranged along the edge of each die area DA of the second wafer W2. One protection pad 245 having the bar shape may be arranged on each side of each die area DA of the second wafer W2.

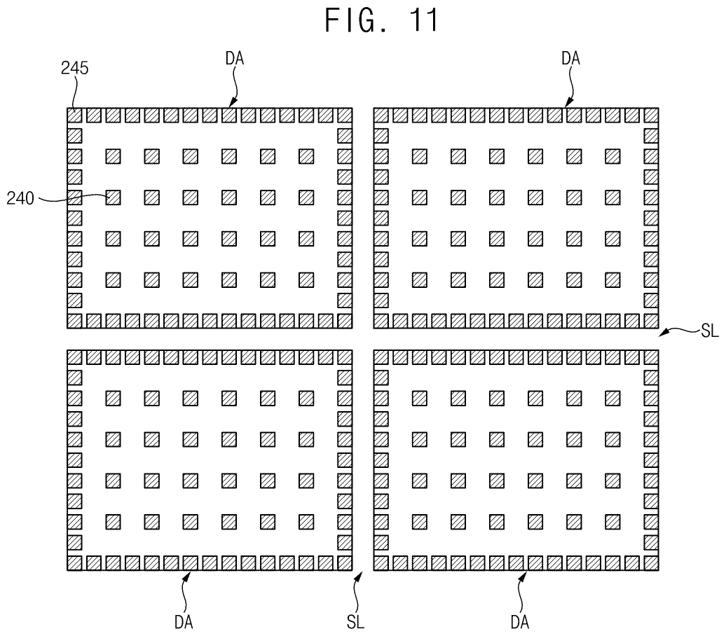

In example embodiments, as illustrated in FIG. 11, the protection pad 245 may have a rectangular shape. A plurality of the protection pads 245 may be arranged along the edge of each die area DA of the second wafer W2. The rectangular shape may be, for example, a rectangle or a square. A plurality of protection pads 245 having the rectangular shape may be spaced apart from each other, and may be arranged on each side of each die area DA of the second wafer W2.

Hereinafter, the protection pad 245 having the shape illustrated in FIG. 9 is described.

In example embodiments, the protection pad 245 may be formed by the same processes as processes for forming of the third conductive pad 240. Thus, the protection pad 245 may include a material the same as a material of the third conductive pad 240. In addition, separate processes for forming the protection pad 245 may not be performed, so that the protection pad 245 may be formed by simple processes.

In example embodiments, the third conductive pad 240 may be formed by processes the same as or similar to processes for forming of the first conductive pad 140.

The third conductive pad 240 and the protective pad 245 may include a metal. In example embodiments, the third conductive pad 240 and the protective pad 245 may include a third seed pattern and third conductive patterns that are sequentially stacked on the second insulating interlayer 230. In this case, the third seed pattern may include, for example, titanium, and the third conductive patterns may include, for example, nickel, gold, etc.

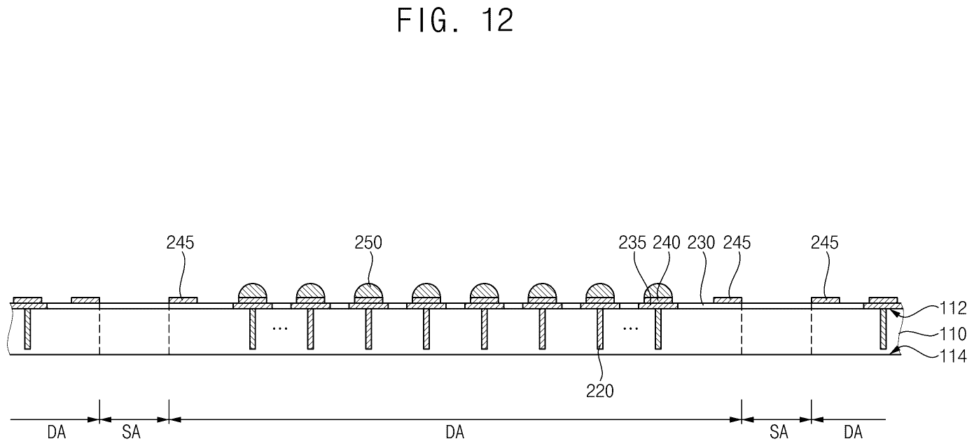

Referring to FIG. 12, a first conductive connecting member 250 may be formed on the third conductive pad 240. In this case, the first conductive connecting member 250 may not be formed on the protective pad 245.

In example embodiments, the first conductive connecting member 250 may be formed by the following processes.

A third photoresist pattern having a third opening exposing the upper surface of the third conductive pad 240 may be formed on the second insulating interlayer 230. A first preliminary conductive connecting member may be formed in the third opening by, for example, an electrolytic plating process or an electroless plating process. After removing the third photoresist pattern, a reflow process may be performed to convert the first preliminary conductive connecting member into a first conductive connecting member 250. In example embodiments, the first conductive connecting member 250 may have a hemispherical shape or an elliptical hemispherical shape.

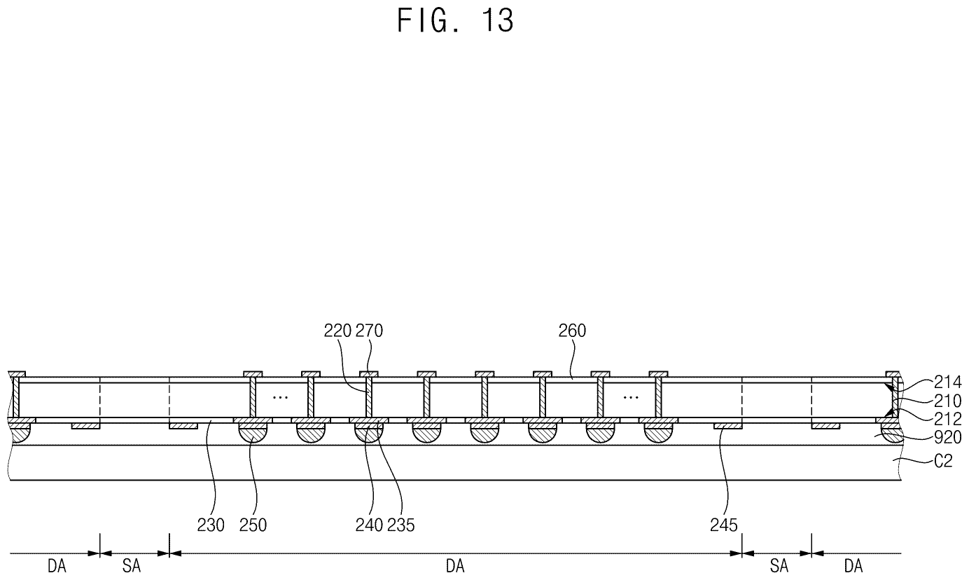

Referring to FIG. 13, processes the same as or similar to the processes described with reference to FIGS. 7 and 8 may be performed.

Particularly, a second temporary adhesive layer 920 may be attached on the second carrier substrate C2. The second temporary adhesive layer 920 may contact an upper surface of the second insulating interlayer on which the second wiring structure 235 is formed and covering the first conductive connecting member 250 and the third conductive pad 240 on the second wafer W2. Therefore, the second carrier substrate C2 may be bonded on the second wafer W2.

After turning over the second wafer W2, a portion adjacent to the second surface 214 of the second substrate 210 may be removed by, for example, a grinding process to expose an upper portion of the second through-electrode structure 220. After forming a second protective layer structure covering a second through-electrode structure 220 on a second surface 214 of a second substrate 210, a planarization process may be performed on the second protective layer structure until the upper surface of the second through-electrode structure 220 is exposed to form a second insulation pattern structure 260. In this case, the second insulation pattern structure 260 may include a plurality of insulation patterns stacked in the vertical direction.

Thereafter, a fourth conductive pad 270 may be formed on the second insulation pattern structure 260 and the second through-electrode structure 220. The fourth conductive pad 270 may include a fourth seed pattern and fourth conductive patterns sequentially stacked in the vertical direction.

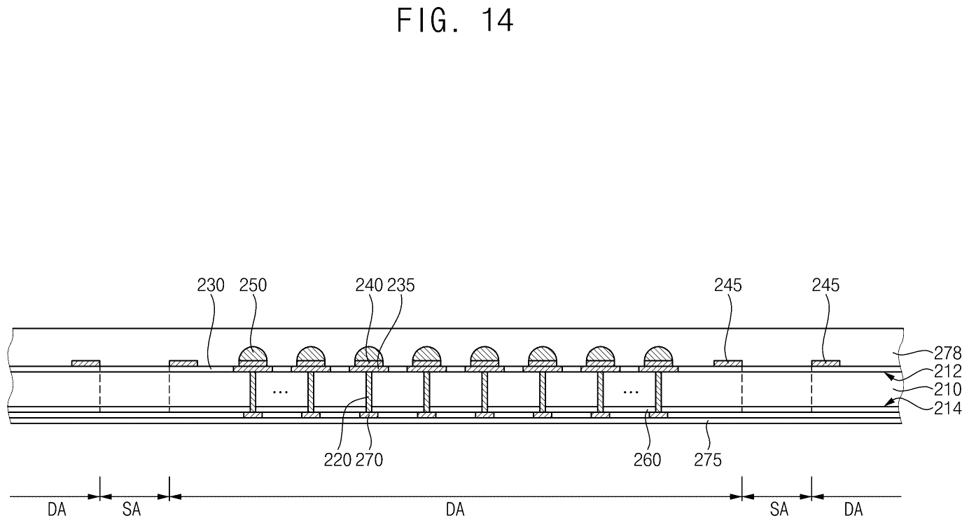

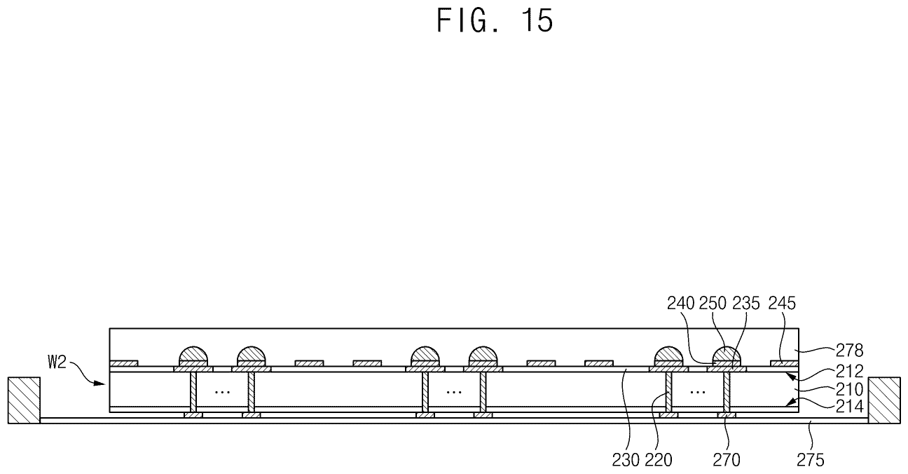

Referring to FIGS. 14 and 15, the second wafer W2 may be turned over, and then the second wafer W2 attached on an upper surface of a release tape 275 formed on a frame having a ring shape.

In this case, the release tape 275 may contact the upper surfaces of the fourth conductive pad 270 and the second insulation pattern structure 260 on the second surface 214 of the second wafer W2.

The second temporary adhesive layer 920 attached on the second carrier substrate C2 may be separated from the first conductive connecting member 250, the third conductive pad 240, and the second insulating interlayer 230. Therefore, the second carrier substrate C2 may be separated from the second wafer W2.

Thereafter, a first preliminary adhesive layer 278 may be formed on the second insulating interlayer 230 so as to cover an entire first surface 212 of the second wafer W2. The first preliminary adhesive layer 278 may cover the first conductive connecting member 250.

In example embodiments, the first preliminary adhesive layer 278 may include a non-conductive film NCF. The first preliminary adhesive layer 278 may include, for example, an epoxy resin, a UV resin, a polyurethane resin, a silicone resin, a silica filler, a thermosetting material, a thermoplastic material, a UV treatment material, etc.

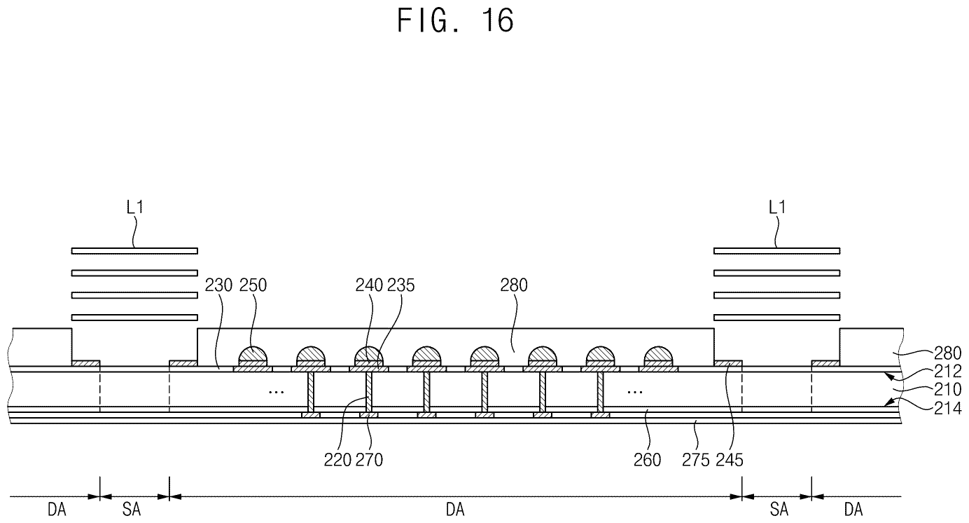

Referring to FIGS. 16 to 18, a portion of the first preliminary adhesive layer 278 may be removed to form the first adhesive layer 280.

The portion where the first preliminary adhesive layer 278 is removed may be the scribe lane area SA of the second wafer W2 and the edge portion within the die area DA of the second wafer W2 adjacent to the scribe lane area SA. Therefore, the first adhesive layer 280 may be formed at a center portion excluding the edge portion within the die area DA of the second wafer W2.

The first preliminary adhesive layer 278 may be removed using the first laser L1. In example embodiments, a portion of the first preliminary adhesive layer 278 may be removed by selectively irradiating the first laser L1 to a removing portion of the first preliminary adhesive layer 278.

In example embodiments, a laser may be selectively irradiated to a removing portion of the first preliminary adhesive layer 278 using a laser generating device for generating the first laser L1 and a high-speed scanner for moving the wafer. In example embodiments, the laser may use a UV laser or a green laser. The laser may have a wavelength of about 343 nm to about 532 nm.

In the die area DA of the second wafer W2, a portion of the first preliminary adhesive layer 278 irradiated with the first laser L1 may face at least a portion of the protective pad 245. The first laser L1 may not be irradiated to the die area inward from the protective pad 245.

The first laser L1 may not be transmitted under the protective pad 245 including a metal. Therefore, since the protective pad 245 is provided, the circuit patterns arranged under the protective pad 245 may be protected from damages due to the first laser. For example, the circuit patterns arranged under the protective pad 245 may be hardly damaged due to the first laser L1.

When the above processes are performed, the first adhesive layer 280 may be spaced apart from the scribe lane area SA, and may be disposed within the die area DA of the second wafer W2. Therefore, a plurality of first adhesive layers 280 may be spaced apart from each other on the second wafer W2. The first adhesive layer 280 may not be formed at least in the scribe lane area SA of the second wafer W2 and the edge area within the die area DA of the second wafer W2 adjacent to the scribe lane area SA. At least a portion of the protective pad 245 may be exposed between the first adhesive layers 280 on the second wafer W2.

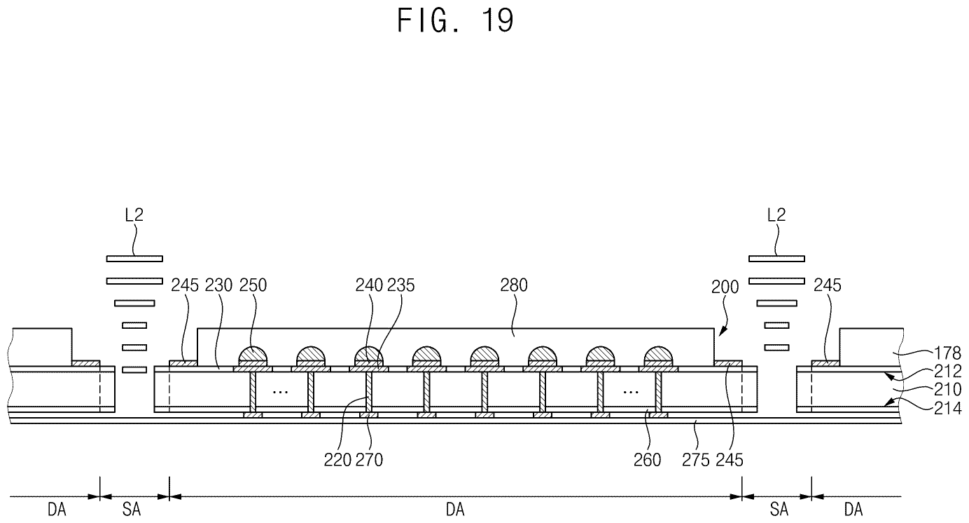

Referring to FIGS. 19 to 21, the second wafer W2 may be cut along the scribe lane area SA. Therefore, the second semiconductor chips 200 formed in die areas DA may be singulated.

The cutting process may be referred to as a sawing process, and the sawing process may include, for example, a laser cutting process or a blade cutting process. In example embodiments, a second laser L2 may be irradiated along a scribe lane area SA of a second wafer W2, so that an individual second semiconductor chip 200 may be formed.

The die area DA may not be removed by the sawing process, and only the scribe lane area SA may be removed. Therefore, a protective pad 245 may be exposed at an edge of the individual second semiconductor chip 200. In addition, the first adhesive layer 280 may not be formed at an edge portion of the upper portion of the individual second semiconductor chip 200, but may be formed only at the central portion of the individual second semiconductor chip 200.

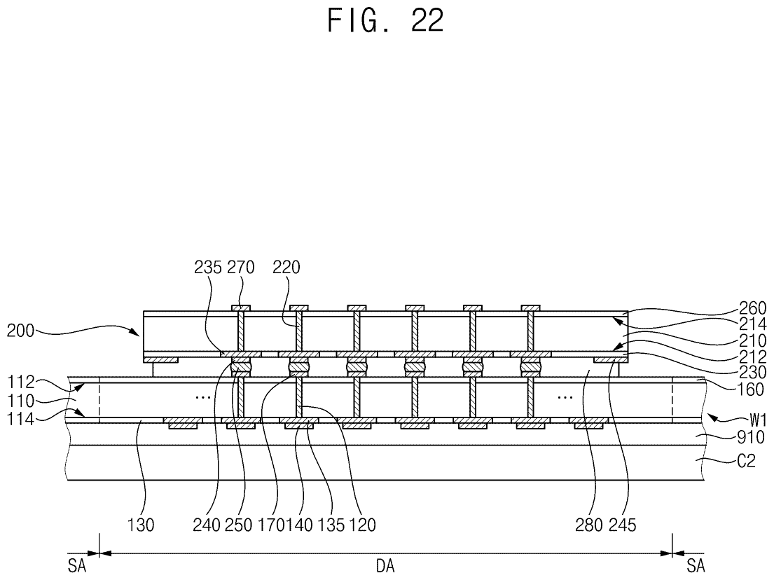

Referring to FIG. 22, the first adhesive layer 280 attached on the second semiconductor chip 200 may contact the second conductive pad 170 of the first wafer W1 and the upper surface of the first insulation pattern structure 160. The second semiconductor chips 200 may be positioned on the first wafer W1. In this case, the second semiconductor chip may be positioned at the first wafer W1 so as to correspond to the die areas DA of the first wafer W1, respectively. The first conductive connecting member 250 of the second semiconductor chip 200 may be positioned so as to correspond to the upper surface of the second conductive pad 170 of the first semiconductor chip 100.

Thereafter, a thermal compression bonding (TCB) process may be performed to attach the second semiconductor chips 200 to the first wafer W1. The thermal compression bonding process includes applying downward pressure to the second semiconductor chips 200 and heating the first conductive connecting member 250. The thermal compression bonding process may be performed at a temperature of, for example, 400° C. or less.

In the thermal compression bonding process, the non-conductive film consisting of the first adhesive layer 280 may be liquefied and fluidized. The non-conductive film may flow laterally within a space between each of the second semiconductor chips 200 and the first wafer W1 and then be hardened. In addition, the first conductive connecting member 250 of the second semiconductor chip 200 may be bonded on the upper surface of the second conductive pad 170 of the first semiconductor chip 100.

In the processes for attaching the second semiconductor chips 200 to the first wafer W1, the first preliminary adhesive layer 278 may not flow to the edge of the second semiconductor chip 200. Accordingly, even after the second semiconductor chips 200 are attached on the first wafer W1, the first adhesive layer 280 may be positioned inward from the sidewall of the second semiconductor chip 200. The lower surface adjacent to the edge of the second semiconductor chip 200 may not be covered by the first adhesive layer 280, and may be exposed by first adhesive layer 280. Even after the second semiconductor chips 200 may be attached on the first wafer W1, the first adhesive layer 280 may not protrude from the edge of the second semiconductor chip 200. In addition, the first adhesive layer 280 may not be attached on the sidewall of the second semiconductor chip 200. The edge of the first adhesive layer 280 may be disposed outward from the first conductive connecting member 250 disposed at outermost of the second semiconductor chip 200. The first adhesive layer 280 may surround all of the first conductive connecting members 250 interposed between the first and second semiconductor chips 100 and 200. A first edge gap 285 may be defined by the sidewall of the first adhesive layer 280, the edge of the upper surface of the first semiconductor chip 100, and the edge of the lower surface of the second semiconductor chip 200.

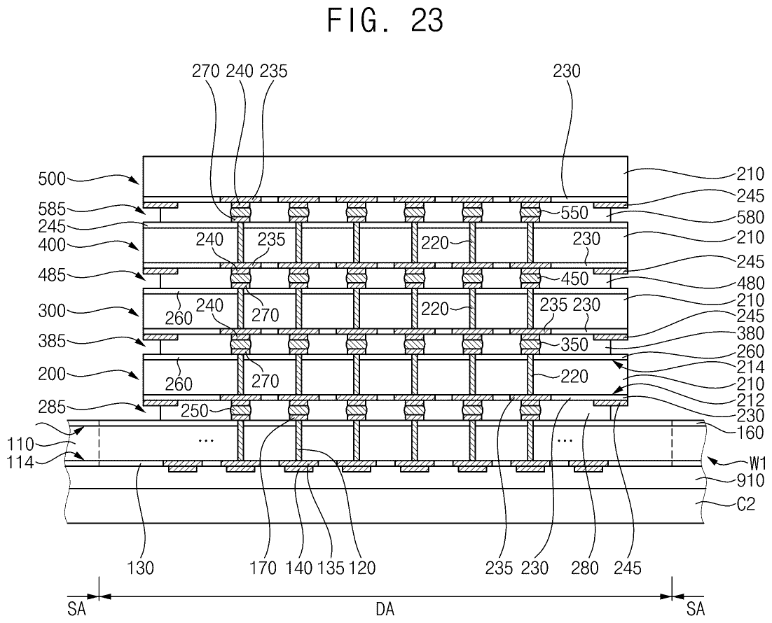

Referring to FIG. 23, the third to fifth semiconductor chips 300, 400 and 500 may be sequentially stacked on the second semiconductor chip 200.

First, the individual third semiconductor chip 300 may be formed by performing processes the same as or similar to processes described with reference to FIGS. 8 to 21. In example embodiments, the third semiconductor chip 300 may be identical to the second semiconductor chip 200.

A third conductive pad 240 electrically connected to the second wiring structure 235 may be formed on the second wiring structure 235 of the third semiconductor chip 300. A protective pad 245 may be formed on the second insulating interlayer 230 of the third semiconductor chip 300. A second conductive connecting member 350 may be formed on the third conductive pad 240.

A second adhesive layer 380 covering the second conductive connecting member 350 may be attached on the third semiconductor chips 300, and the third semiconductor chips 300 may be singulated. At least a portion of the protective pad 245 may be exposed at the edge of the individual third semiconductor chip 300. In addition, the second adhesive layer 380 may be formed only at the center portion of the upper portion of the individual third semiconductor chip 300, and may not be formed at the edge portion of the upper portion of the individual third semiconductor chip 300.

Thereafter, the third semiconductor chip 300 may be stacked on the second semiconductor chip 200 by performing processes the same as or similar to the processes described with reference to FIG. 22.

In example embodiments, the third semiconductor chip 300 may be stacked on the second semiconductor chip 200 through the thermal compression bonding process. In this case, the second conductive connecting member 350 of the third semiconductor chip 300 may be bonded on the fourth conductive pad 270 of the second semiconductor chip 300 corresponding thereto.

In the process for attaching the third semiconductor chip 300 to the second semiconductor chip 200, the second adhesive layer 380 may not flow to the edge of the second semiconductor chip 200. Therefore, even after the third semiconductor chip 300 is attached on the second semiconductor chip 200, the second adhesive layer 380 may be positioned inward from the sidewalls of the second and third semiconductor chips 200 and 300. The lower surface adjacent to the edge of the third semiconductor chip 300 may not be covered by the second adhesive layer 380, and may be exposed. Even after the third semiconductor chip 300 is attached on the second semiconductor chip 200, the second adhesive layer 380 may not have a portion protruding outward from the edges of the second and third semiconductor chips 200 and 300. In addition, the second adhesive layer 380 may not be attached on the sidewalls of the second and third semiconductor chips 200 and 300. The edge of the second adhesive layer 380 may be positioned outward from the second conductive connecting member 350 positioned at the outermost edge. The second adhesive layer 380 may surround all of the second conductive connecting members 350 interposed between the second and third semiconductor chips 200 and 300. A second edge gap 385 may be defined by the sidewall of the second adhesive layer 380, the edge of the upper surface of the second semiconductor chip 200, and the edge of the lower surface of the third semiconductor chip 300.

In the same manner as described above, a fourth semiconductor chip 400 may be stacked on the third semiconductor chip 300. In example embodiments, the fourth semiconductor chip 400 may be identical to the third semiconductor chip 300.

Particularly, a third conductive pad 240 electrically connected to the second wiring structure may be formed on the second wiring structure 235 of the fourth semiconductor chip 400. In addition, a protective pad 245 may be formed on the second insulating interlayer 230 of the fourth semiconductor chip 400. A third conductive connecting member 450 may be formed on the third conductive pad 240.

In addition, a third adhesive layer 480 may be attached on the fourth semiconductor chip 400, and the fourth semiconductor chips 400 may be singulated. The third adhesive layer 480 may not be formed on the edge portion of the upper portion of an individual fourth semiconductor chip 400, but may be formed only on the center portion of the upper portion of an individual fourth semiconductor chip 400.

Thereafter, the fourth semiconductor chip 400 may be stacked on the third semiconductor chip 300 through a thermal compression bonding process. Even after the fourth semiconductor chip 400 is attached on the third semiconductor chip 300, the third adhesive layer 480 may be positioned inward from the sidewalls of the third and fourth semiconductor chips 300, 400. In addition, the third adhesive layer 480 may not be attached on the sidewalls of the third and fourth semiconductor chips 300, 400. A third edge gap 485 may be defined by the sidewall of the third adhesive layer 480, the edge of the upper surface of the third semiconductor chip 300, and the lower portion of the edge of the surface of the fourth semiconductor chip 400.

A fifth semiconductor chip 500 may be sequentially stacked on the fourth semiconductor chip 400.

The fifth semiconductor chip 500 may be formed by performing processes the same as or similar to processes described with reference to FIGS. 8 to 21. However, the fifth semiconductor chip 500 may not have a through-electrode structure passing through the substrate. Therefore, the process of forming a through-electrode structure may not be performed.

Thereafter, the fifth semiconductor chip 500 may be stacked on the fourth semiconductor chip 400 in the same manner as described above.

Particularly a third conductive pad 240 contacting the second wiring structure 235 may be formed on the second insulating interlayer 230, and the third conductive pad 240 may be electrically connected to the second wiring structure 235. A protective pad 245 may be formed on the second insulating interlayer 230 of the fifth semiconductor chip 500. A fourth conductive connecting member 550 may be formed on the third conductive pad 240.

In addition, a fourth adhesive layer 580 may be attached to the fifth semiconductor chips 500, and the fifth semiconductor chips 500 may be singulated. The fourth adhesive layer 580 may not be formed on the edge portion of the upper portion of an individual fifth semiconductor chip 500, but may be formed only on the center portion of the upper portion of an individual fifth semiconductor chip 500.

Thereafter, the fifth semiconductor chip 500 may be stacked on the fourth semiconductor chip 400 by a thermal compression bonding process. Even after the fifth semiconductor chip 500 is attached on the fourth semiconductor chip 400, the fourth adhesive layer 580 may be positioned inward from the sidewalls of the fourth and fifth semiconductor chips 400 and 500. A fourth edge gap 585 may be defined by the sidewall of the fourth adhesive layer 580, the edge of the upper surface of the fourth semiconductor chip 400, and the edge of the lower surface of the fifth semiconductor chip 500.

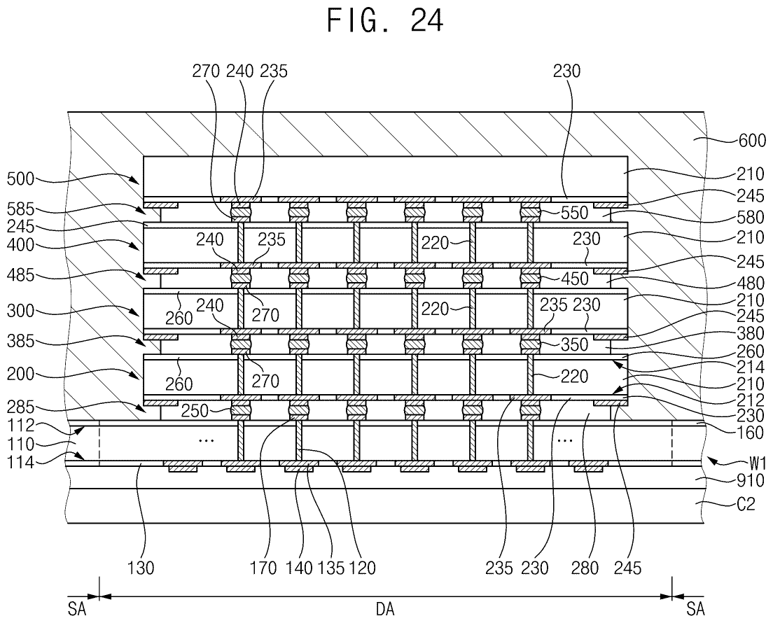

Referring to FIG. 24, a molding member 600 covering a stacked structure including the second to fifth semiconductor chips 200, 300, 400 and 500 may be formed on the first wafer W1. The molding member 600 may cover the sidewalls of the second to fifth semiconductor chips 200, 300, 400 and 500 and the sidewalls of the first to fourth adhesive layers 280, 380, 480 and 580.

The molding member 600 may fill the first to fourth edge gaps 285, 384, 485 and 585. The molding member 600 may include, for example, an epoxy molding compound EMC.

In example embodiments, the molding member 600 may be formed to cover the upper portion of the fifth semiconductor chip 500. In some example embodiments, the upper portion of the molding member 600 may be removed so that an upper surface of the fifth semiconductor chip 500 may be exposed by the molding member 600.

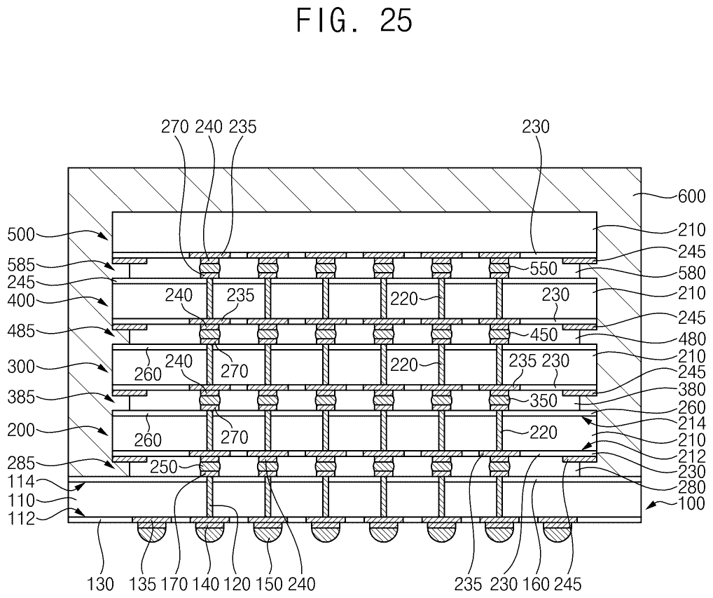

Referring to FIG. 25, the first wafer W1 may be cut along the scribe lane area SA by, for example, a sawing process. Therefore, the first semiconductor chips 100 may be singulated.

During the sawing process, the molding member 600 may also be cut. Accordingly, a structure in which the second to fifth semiconductor chips 200, 300, 400 and 500 are stacked on the individual first semiconductor chips 100 may be formed.

The first temporary adhesive layer 910 and the first carrier substrate C1 may be separated from each of the first semiconductor chips 100.

Thereafter, the first external connecting member 150 may be formed on the first conductive pad 140 included in the first semiconductor chip 100. In some example embodiments, the process for forming the first external connecting member may be omitted.

A semiconductor package can be manufactured by the above process.

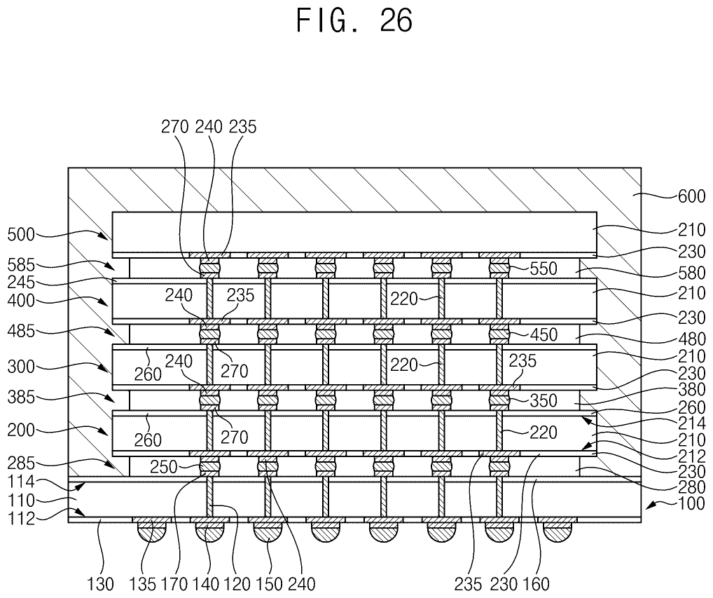

FIG. 26 is a cross-sectional view illustrating a semiconductor package according to example embodiments.

Referring to FIG. 26, the semiconductor package may be the same as the semiconductor package illustrated in FIG. 1, except that the second to fifth semiconductor chips 200, 300, 400 and 500 do not include protection pads. When the substrate area for forming the protection pads is not secured, the protection pads may not be formed.

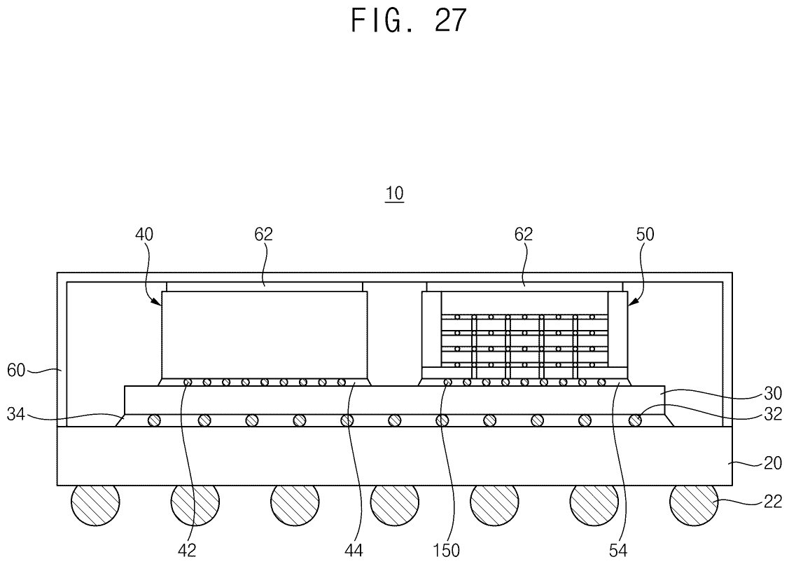

FIG. 27 is a cross-sectional view illustrating an electronic device according to example embodiments.

The electronic device includes the semiconductor package illustrated in FIG. 1 as a second semiconductor device 50. However, the concept of the present invention is not limited thereto, and the electronic device may also include the semiconductor package illustrated in FIG. 25 as a second semiconductor device 50.

Referring to FIG. 27, the electronic device 10 may include a package substrate 20, an interposer 30, and first and second semiconductor devices 40 and 50. The electronic device 10 may further include first to third underfill members 34, 44 and 54, a heat slug 60, and a heat dissipation member 62.

In example embodiments, the electronic device 10 may be a memory module having a 2.5D package structure, and thus the electronic device 10 may include an interposer 30 for electrically connecting the first and second semiconductor devices 40 and 50 to each other.

In example embodiments, the first semiconductor device 40 may include a logic device, and the second semiconductor device 50 may include a memory device. The logic device may include, for example, an application-specific integrated circuit ASIC chip including a central processing unit CPU, a graphics processing unit GPU, a microprocessor, a microcontroller, an application processor AP, a digital signal processing core, etc. The memory device may include, for example, a semiconductor package such as an HBM package.

In example embodiments, the package substrate 20 may have an upper surface and a lower surface facing each other in the vertical direction. The package substrate 20 may include, for example, a printed circuit board (PCB). The printed circuit board may be a multilayer circuit board having various circuit patterns therein.

The interposer 30 may be mounted on the package substrate 20 through a fifth conductive connecting member 32. In example embodiments, the interposer 30 may be positioned within an area where the package substrate 20 is formed, in a plan view. A planar area of the interposer 30 may be smaller than a planar area of the package substrate 20.

The interposer 30 may be a silicon interposer including a plurality of wirings therein or a re-distribution layer (RDL) interposer. The first semiconductor device 40 and the second semiconductor device 50 may be connected to each other by the wirings inside the interposer 30, or the first semiconductor device 40 and the second semiconductor device 50 may be electrically connected to the package substrate 20 by the fifth conductive connecting member 32. The fifth conductive connecting member 32 may include, for example, a micro bump. The silicon interposer may provide a high-density interconnection between the first and second semiconductor devices 40 and 50.

The first semiconductor device 40 may be disposed on the interposer 30, and the first semiconductor device 40 may be mounted on the interposer 30 by, for example, a flip chip bonding process. In this case, the first semiconductor device 40 may be mounted on the interposer 30 so that an active surface on which the conductive pads are formed may be positioned below to face the interposer 30. The conductive pads of the first semiconductor device 40 may be electrically connected to the conductive pads of the interposer 30 through the sixth conductive connecting member 42. The sixth conductive connecting member 42 may include, for example, a micro bump.

Alternatively, the first semiconductor device 40 may be mounted on the interposer 30 by a wire bonding process. In this case, the active surface of the first semiconductor device 40 may be positioned above.

The second semiconductor device 50 may be disposed on the interposer 30, and the second semiconductor device 50 may be spaced apart from the first semiconductor device 40 in the horizontal direction. The second semiconductor device 50 may be mounted on the interposer 30 by, for example, a flip chip bonding process. In this case, the conductive pads of the second semiconductor device 50 may be electrically connected to the conductive pads of the interposer 30 through the first external connecting member 150.

Although only one first semiconductor device 40 and one second semiconductor device 50 may be disposed on the interposer 30 in the FIG. 27, the concept of the present invention is not limited thereto, and a plurality of first semiconductor devices 40 and a plurality of second semiconductor devices 50 may be disposed on the interposer 30. In example embodiments, a first underfill member 34 may fill a space between the interposer 30 and the package substrate 20. A second underfill member 44 may fill a space between the first semiconductor device 40 and the interposer 30, and a third underfill member 54 may fill a space between the second semiconductor device 50 and the interposer 30.

The first to third underfill members 34, 44 and 54 may include a material having relatively high fluidity so as to effectively fill a small space between one of the first and second semiconductor devices 40 and 50 and the interposer 30 or a small space between the interposer 30 and the package substrate 20. For example, each of the first to third underfill members 34, 44 and 54 may include an adhesive including an epoxy.

The second semiconductor device 50 may include a plurality of stacked semiconductor chips. The second semiconductor device 50 may include, for example, a buffer chip and a plurality of memory chips sequentially stacked on the buffer chip. The buffer chip and the memory chips may be electrically connected to each other by through-electrodes such as through-silicon vias (TSVs), and the through-electrodes may be electrically connected to the conductive connecting members. The buffer chip and the memory chips may communicate data signals and control signals by the through-electrodes.

As described above, in the second semiconductor device 50, the adhesive layer may be interposed between semiconductor chips, and each of the adhesive layers may be provided inward from a sidewall of the semiconductor chip so as not to protrude outward from the edge of the semiconductor chip. Accordingly, when the second semiconductor device 50 is mounted on the interposer, a stress may be decreased, reliability increased, and the potential for failure may be decreased.

In example embodiments, a heat slug 60 may cover the first and second semiconductor devices 40 and 50 on the package substrate 20 so as to conduct heat from the first and second semiconductor devices 40 and 50. Meanwhile, a heat dissipation member 62 may be disposed on the upper surface of each of the first and second semiconductor devices 40 and 50, and the heat dissipation member 62 may include, for example, a thermal interface material TIM. The heat slug 60 may conduct heat from the first and second semiconductor devices 40 and 50 by the heat dissipation member 62.

A conductive pad may be formed on a lower surface of the package substrate 20, and the second external connecting member 22 may be electrically connected to the lower surface of the conductive pad. In example embodiments, a plurality of the second external connecting members 22 may be spaced apart from each other in the horizontal direction. The second external connecting members 22 may include, for example, solder balls. The electronic device 10 may be mounted on a module substrate via the second external connecting member 22 to form a memory module.

While the present disclosure has illustrated and described example embodiments of the inventive concept, it will be understood by those of ordinary skill in the art that various changes in form and details may be made thereto without departing from the scope of the present inventive concept as set forth by the following claims.

What is claimed is:

1. A semiconductor package, comprising:
semiconductor chips including a first semiconductor chip and second semiconductor chips stacked on the first semiconductor chip in a vertical direction;
adhesive layers interposed between vertically adjacent semiconductor chips, wherein edges of the adhesive layers are positioned inward from sidewalls of the second semiconductor chips; and
a molding member on the first semiconductor chip, the molding member covering the sidewalls of the second semiconductor chips and sidewalls of the adhesive layers, and the molding member filling edge gaps between the vertically adjacent semiconductor chips and extending to sidewalls of a respective adhesive layer between the vertically adjacent semiconductor chips.

2. The semiconductor package of claim 1, wherein the sidewalls of the adhesive layers are aligned with each other in the vertical direction.

3. The semiconductor package of claim 1, wherein at least one of the sidewalls of a first adhesive layer of the adhesive layers is not aligned with any sidewalls of a second adhesive layer of the adhesive layers in the vertical direction.

4. The semiconductor package of claim 1, further comprising protective pads, each including a metal,
wherein the protective pads are each disposed at an edge portion of a lower surface of a corresponding one of the second semiconductor chips.

5. The semiconductor package of claim 4, wherein for each second semiconductor chip of the second semiconductor chips, the protective pads surround an interior portion of the lower surface of the second semiconductor chip

6. The semiconductor package of claim 5, wherein the protective pads each have a ring shape, a bar shape, or a square shape.

7. The semiconductor package of claim 4, wherein the molding member contacts at least a portion of each of the protective pads.

8. The semiconductor package of claim 1, wherein the molding member contacts the sidewalls of the adhesive layers and an upper surface of a lower one of the vertically adjacent semiconductor chips and a lower surface of an upper one of the vertically adjacent semiconductor chips.

9. The semiconductor package of claim 1, wherein each of the adhesive layers includes a non-conductive film NCF, and the molding member includes an epoxy molding compound EMC.

10. The semiconductor package of claim 1, wherein at least one set of the vertically adjacent semiconductor chips comprises an upper second semiconductor chip and a lower second semiconductor chip, each of the upper second semiconductor chip and the lower second semiconductor chip comprising:
a substrate;
a through-electrode structure passing through the substrate;
a first conductive pad on a lower surface of the substrate, the first conductive pad electrically connected to the through-electrode structure; and
a second conductive pad on an upper surface of the substrate, the second conductive pad electrically connected to the through-electrode structure, and
wherein a conductive connecting member is interposed between the first conductive pad of the upper second semiconductor chip and the second conductive pad of the lower second semiconductor chip.

11. The semiconductor package of claim 10, wherein each of the second semiconductor chips comprises a protective pad formed of the same material as the conductive pad.

12. The semiconductor package of claim 10, wherein each of the upper second semiconductor chip and the lower second semiconductor chip includes a protective pad that is not electrically connected to the through-electrode structures of either the upper second semiconductor chip or the lower second upper semiconductor chip.

13. A semiconductor package comprising:
semiconductor chips including a first semiconductor chip, second semiconductor chips stacked on the first semiconductor chip in a vertical direction, and a third semiconductor chip stacked on the second semiconductor chips in a vertical direction;
adhesive layers interposed between vertically adjacent semiconductor chips, wherein edges of the adhesive layers are positioned inward from sidewalls of the second semiconductor chips; and
a molding member covering the sidewalls of the second semiconductor chips and sidewalls of the adhesive layers, the molding member contacting the sidewalls of the adhesive layers and edge portions of upper surfaces and lower surfaces of the second semiconductor chips,
wherein each of the second semiconductor chips comprises:
a substrate;
through-electrode structures passing through the substrate;
first conductive pads on a lower surface of the substrate, the first conductive pads electrically connected to the through-electrode structures, respectively;
second conductive pads on an upper surface of the substrate, the second conductive pads electrically connected to the through-electrode structures, respectively; and
a protective pad on an edge portion of the lower surface of the substrate, the protective pad including a material that is the same material included in the second conductive pads.

14. The semiconductor package of claim 13, wherein the edges of each of the adhesive layers are aligned in the vertical direction.

15. The semiconductor package of claim 13, wherein an edge of a first adhesive layer of the adhesive layers is not aligned with any sidewalls of a second adhesive layer of the adhesive layers in the vertical direction.

16. The semiconductor package of claim 13, wherein the molding member fills edge gaps between each of the vertically adjacent semiconductor chips, each edge gap extending to the sidewalls of a respective adhesive layer.

17. The semiconductor package of claim 13, wherein the molding member contacts at least a portion of each of the protective pads.

18. The semiconductor package of claim 13, wherein each of the adhesive layers include a non-conductive film and the molding member includes an epoxy molding compound.

19. A semiconductor package, comprising:
a first semiconductor chip including logic circuitry;
a second semiconductor chip, a third semiconductor chip, and a fourth semiconductor chip sequentially stacked in a vertical direction on the first semiconductor chip, the second semiconductor chip, the third semiconductor chip, and the fourth semiconductor chips each including memory circuitry;
non-conductive films including a first non-conductive film interposed between the first semiconductor chip and the second semiconductor chip, a second non-conductive film interposed between the second semiconductor chip and the third semiconductor chip, and a third non-conductive film interposed between the third semiconductor chip and the fourth semiconductor chip in the vertical direction to bond the first semiconductor chip, the second semiconductor chip, the third semiconductor chip, and the fourth semiconductor chips together, and edges of the non-conductive films being positioned inward from sidewalls of the second semiconductor chip, the third semiconductor chip, and the fourth semiconductor chip;
an epoxy molding compound covering the sidewalls of the second semiconductor chip, the third semiconductor chip, and the fourth semiconductor chip and sidewalls of the non-conductive films, the epoxy molding compound filling edge gaps between the first semiconductor chip and the second semiconductor chip, the second semiconductor chip and the third semiconductor chip, and the third semiconductor chip and the fourth semiconductor chip, the edge gaps extending to the sidewalls of the non-conductive films; and
a protective pad including a metal material disposed at an edge portion of a lower surface of at least one of the second semiconductor chip, the third semiconductor chip, and the fourth semiconductor chip.

20. The semiconductor package of claim 19, wherein the second semiconductor chip, and the third semiconductor chip each include a substrate and a through-electrode structures passing through the substrate, and a respective protective pad is not electrically connected to the through-electrode structure.
